(19) United States
(12) Patent Application Publication
(10) Pub. No.: US 2026/0237438 A1
(43) Pub. Date: Aug. 13, 2026

(54) WEIGHT UPDATES ON MEMORY DEVICE DURING TRAINING

(71) Applicant: Micron Technology, Inc., Boise, ID (US)

(72) Inventors: Hernan Castro, Shingle Springs, CA (US); Fabio Pellizzer, Boise, ID (US)

(21) Appl. No.: 19/425,620

(22) Filed: Dec. 18, 2025

Related U.S. Application Data
(60) Provisional application No. 63/757,097, filed on Feb. 11, 2025.

(51) Int. Cl. G11C 16/10; G11C 16/08; G11C 16/24; G11C 16/30

(52) U.S. Cl. CPC G11C 16/102; G11C 16/08; G11C 16/24; G11C 16/30

(57) ABSTRACT

Systems, methods, and apparatus related to memory devices that perform multiplication using memory cells. In one approach, a memory array stores synaptic weights in memory cells. A controller updates the weights by incrementally changing the threshold voltages of the memory cells in a same direction of change. This permits parallel updates of the weights. Each parallel update is performed in two phases of cell programming.

### RELATED APPLICATIONS

The present application claims priority to Prov. U.S. patent application Ser. No. 63/757,097 filed Feb. 11, 2025, the entire disclosure of which application is hereby incorporated herein by reference.

### TECHNICAL FIELD

At least some embodiments disclosed herein relate to memory devices in general and more particularly, but not limited to, updating weights on a memory device during training of a neural network.

### BACKGROUND

Limited memory bandwidth is a significant problem in machine learning systems. For example, DRAM devices used in current systems store large amounts of weights and activations used in deep neural networks (DNNs).

In one example, deep learning machines, such as those supporting processing for convolutional neural networks (CNNs), perform processing to determine a huge number of calculations per second. For example, input/output data, deep learning network training parameters, and intermediate results are constantly fetched from and stored in one or more memory devices (e.g., DRAM). A DRAM type of memory is typically used due to its cost advantages when large storage densities are involved (e.g., storage densities greater than 100 MB). In one example of a deep learning hardware system, a computational unit (e.g., a system-on-chip (SOC), FPGA, CPU, or GPU) is attached to a memory device(s) (e.g., a DRAM device).

Existing computer architectures use processor chips specialized for serial processing and DRAMs optimized for high density memory. The interface between these two devices is a major bottleneck that introduces latency and bandwidth limitations and adds a considerable overhead in power consumption. Memory on-chip is area expensive and it is not possible to add large amounts of memory to the CPU and GPU processors currently used to train and deploy DNNs.

Memory in neural networks is used to store input data, weight parameters and activations as an input propagates through the network. In training, activations from a forward pass must be retained until they can be used to calculate the error gradients in the backwards pass. As an example, a network can have 26 million weight parameters and compute 16 million activations in a forward pass. If a 32-bit floating-point value is used to store each weight and activation, this corresponds to a total storage requirement of 168 MB.

GPUs and other machines need significant memory for the weights and activations of a neural network. GPUs cannot efficiently execute directly the small convolutions used in deep neural networks, so they need significant activation or weight storage. Finally, memory is also required to store input data, temporary values and program instructions. For example, a high performance GPU may need over 7 GB of local DRAM.

Large amounts of storage data cannot be kept on the GPU processor. In many cases, high performance GPU processors may have only 1 KB of memory associated with each of the processor cores that can be read fast enough to saturate the floating-point data path. Thus, at each layer of a DNN, the GPU needs to save the state to external DRAM, load up the next layer of the network, and then reload the data. As a result, the off-chip memory interface suffers the burden of constantly reloading weights and saving and retrieving activations. This significantly slows down training time and increases power consumption.

In one example, image and other sensors are used and generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having an image sensing pixel array, a memory cell array with tiles, and circuits to perform inference computations according to one embodiment.

FIG. 2 shows the computation of a column of weight bits multiplied by a column of input bits to provide an accumulation result according to one embodiment.

FIG. 3 shows a method of computation in an integrated circuit device based on summing output currents from memory cells according to one embodiment.

FIG. 4 shows an analog weight-stationary architecture for matrix vector multiplication (MVM) according to one embodiment.

FIG. 5 shows a three-dimensional memory cell array having floating gate memory cells in a NOR configuration according to one embodiment.

FIG. 6 shows an architecture having resistive random access memory (RRAM) or NOR memory cells arranged in a parallel configuration for performing multiplication according to one embodiment.

FIG. 7 shows a four-quadrant implementation of a synapse according to one embodiment.

FIGS. 8-9 show pillars having memory cells that store weights using bits of varying significance according to some embodiments.

FIG. 10 shows a pillar having memory cells that store weights using unary coding according to one embodiment.

FIG. 11 shows a pillar having memory cells that store weights using 2× unary coding according to one embodiment.

FIG. 12 shows a pillar having top and bottom select transistors according to one embodiment.

FIG. 13 shows an exemplary memory cell distribution of initial threshold voltages.

FIG. 14 shows an exemplary memory cell distribution of initial output currents.

FIG. 15 shows an exemplary memory cell distribution of output currents after performing multiple programming loops according to one embodiment.

FIG. 16 shows an exemplary memory cell distribution of threshold voltages after performing multiple programming loops according to one embodiment.

FIG. 17 shows a method for programming memory cells used to perform multiplication by accumulating output currents according to one embodiment.

FIG. 18 shows an exemplary value encoded in a dense memory array and a corresponding encoding of the value in a sparse memory array according to one embodiment.

FIG. 19 shows another exemplary value encoded in a dense memory array and a corresponding encoding of the value in a sparse memory array according to one embodiment.

FIG. 20 shows an exemplary graph of a probability to increment a memory cell versus a number of write pulses.

FIG. 21 shows a portion of a memory array having four synapses connected to digit lines used to accumulate output currents from memory cells of the synapses according to one embodiment.

FIG. 22 shows a four-quadrant synapse definition.

FIGS. 23-24 show parallel updating of synaptic weights by programming memory cells in two phases according to one embodiment.

FIG. 25 shows an exemplary graph of cumulative synaptic weight value versus a number of increments or decrements to the synaptic weight.

FIG. 26 shows an increment array and a baseline array according to one embodiment.

FIG. 27 shows exemplary encoding of an input signal and a synaptic weight according to one embodiment.

FIG. 28 shows a method for updating weights on a memory device during training of a neural network according to one embodiment.

### DETAILED DESCRIPTION

The following disclosure describes various embodiments for three-dimensional memory cell arrays in a NOR configuration that are used for performing multiplication and other operations in memory devices. The memory device may, for example, store data used by a host device (e.g., a computing device of an autonomous vehicle, or another computing device that accesses data stored in the memory device). In one example, the memory device is a solid-state drive mounted in an electric vehicle.

In one example, selected memory cell tiles are configured dynamically as the computations for a neural network progress (e.g., move from one layer to another layer). For example, these computations include matrix vector multiplication (MVM) for each layer of the neural network. The weights for the neural network are stored in the memory cell array and multiplication using the weights is performed in the memory cell array itself based on output currents from memory cells in the array. The output currents are digitized and used by a controller to support the MVM.

Improved power efficiency is particularly desirable for use of neural networks on mobile devices and automobiles. Storing the weights for a neural network in the memory device and doing the multiplication in the memory device avoids or reduces the need to move the weights to a central processing unit or other processing device. This reduces the power consumption required to move data to and from memory, and also reduces the memory bandwidth problem described herein.

Various memory device structures may be used for forming a memory cell array. For example, several hardware accelerators based on in-memory compute are can use SRAM, RRAM, or NAND flash memory. However, energy efficiency (power) remains a major bottleneck for inference applications even if using these exemplary accelerators. Further, planar NOR-based schemes exhibit lower density.

More generally, neural networks are one of the most popular classes of machine learning algorithm (e.g., modeled after our understanding of how the brain works). For example, a network has a large number of neurons that on their own perform fairly simple computations, but together can learn complex and non-linear functions. For example, neuron computation is basically multiplication of multiple input values by neuron weights (which represent how important each input is to the computation), and summing of the results. The weights are learned during network training. Each result is then passed through a non-linear activation function to allow the neuron to learn complex relationships.

In terms of computational burden, the multiplication of all input values by neuron weights for all neurons in the network is the most demanding use of processing power. For example, this multiplication can be 90% or more of the computational requirement, depending on the network design. When scaled to a full layer of the neural network, the computation is vectorized and becomes a matrix vector multiplication problem. The computations are also sometimes referred to as dot product or sum-of-products (SOP) computations.

Deep learning technologies are an exemplary implementation of neural networks and have been playing a significant role in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge AIs).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for AI applications, larger DNN models are developed and implemented with huge amounts of weights and activations. The resulting bottlenecks of memory bandwidth and power consumption on inter-chip data movement are significant technical problems.

Over time, neural networks continue to grow exponentially in complexity, which means there are many more computations required. This stresses the performance of traditional computation architectures. For example, purpose-built compute blocks are needed for the MVM operation to meet performance requirements (GPUs, Digital Accelerators). Also, neuron weights must be fetched from memory, which both causes performance bottlenecks, and is energy inefficient, as mentioned above.

In some cases, the precision of the computations can be reduced to address these concerns. For example, the selection of the type of neural network training can enable roughly equivalent neural network accuracy with significantly lower precision. The lower precision can improve the performance and/or energy efficiency of a neural network implementation. Also, the use of a lower precision can be supportive of storing weights in memory and performing multiplication in the memory, as described herein.

A neural network design itself typically dictates the size of the MVM operation at every layer of the network. Each layer can have a different number of features and neurons. In one embodiment, the MVM computation will take place in a portion of a memory array. This portion is represented in the array as one or more selected tiles.

To address these and other technical problems, a memory device integrates memory and processing. In one example, memory and inference computation processing are integrated in the same integrated circuit device. In some embodiments, the memory device is an integrated circuit device having an image sensing pixel array, a memory cell array, and one or more circuits to use the memory cell array to perform inference computation on image data from image sensors. In some embodiments, the memory device includes or is used with other types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

In one embodiment, a three-dimensional NOR-based accelerator is used to perform multiply accumulate (MAC) to mitigate challenges with power consumption. For example, this approach significantly increases tera operations per watt (TOPS/W) and improves energy efficiency (e.g., by 5-10 times or more).

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

The threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line (e.g., a global digit line or GDL) for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted (e.g., left shifted) to apply the weights of the respective significant bits for summation to obtain the results of multiplications of multi-bit weights and multi-bit inputs with accumulation.

Using the capability of performing multiplication and accumulation operations implemented via memory cell arrays, a logic circuit can be configured to perform inference computations, such as the computation of an artificial neural network.

In one embodiment, a three-dimensional NOR memory device includes a memory cell array having memory cells stacked vertically (e.g., in vertical pillars having multiple tiers). Each memory cell stores a weight for use in a multiplication (e.g., MVM) or other operation. Local digit lines are connected to current terminals of the memory cells. The local digit lines extend vertically above a semiconductor substrate. Select transistors are connected to the local digit lines. Select lines are used to control the select transistors, and to encode an input pattern to multiply by the stored weights. Accumulation circuitry accumulates output currents from the memory cells to determine a result of the multiplication.

In one embodiment, a three-dimensional NOR memory device includes a memory cell array having memory cells stacked vertically above a semiconductor substrate. Each memory cell stores a weight for use in a multiplication or other operation. Each memory cell has a current channel extending in a horizontal direction (parallel with the top surface of the semiconductor substrate). Wordlines are connected to gates of the memory cells. The wordlines are used to encode an input pattern to multiply by the stored weights. Accumulation circuitry accumulates output currents from the memory cells to determine a result of the multiplication.

In one embodiment, a memory device includes a semiconductor substrate, and transistors stacked vertically in pillars above the substrate. Each transistor has a semiconductor layer to provide a channel, and a gate layer (e.g., ONO stack) that wraps around at least half or all of a circumference of the semiconductor layer. Wordlines are used to apply gate voltages to the transistors. In one embodiment, a portion of each wordline wraps around at least half of a circumference of the gate layer of each transistor. In one example, the wordline wraps fully around the gate layer of each transistor.

Various embodiments of memory devices performing multiplication using logical states of memory cells are now described below. A memory device typically has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications.

The memory cells in the array are NOR flash memory cells. In one example, floating gate or charge trap memory devices in NOR memory configurations are used.

In one embodiment, a memory device (e.g., integrated circuit device 101) includes a memory cell array having memory cells. Each memory cell is programmable to store a respective weight for performing a multiplication. The integrated circuit device also includes voltage drivers configured to apply input voltages to the memory cells for performing the multiplication. The input voltages represent an input to be multiplied by the respective weight for each memory cell.

The integrated circuit device has a common line coupled to the memory cells. The common line is configured to sum output currents from each of the memory cells that result from applying the input voltages. The integrated circuit device has a digitizer configured to generate a result for the multiplication based on the summed output currents.

In one embodiment, a memory device implements unsigned 1-bit to 1-bit multiplication. Each memory cell can be programmed to a “1-state” such that a predetermined amount of current can go through the memory cell when a voltage V is applied across the memory cell (e.g., across two terminals of a memory cell). Alternatively, the memory cell can be programmed to a “0-state” such that only a negligible amount of current can go through the memory cell when the same voltage V is applied. Thus, the memory cells can be programmed to the “1-state” or the “0-state” to represent a stored weight of “1” or “0” respectively.

An input voltage of V can be used to represent an input of “1”; and an input voltage of 0 can be used to represent an input of “0”. Alternatively, another voltage can be used to represent an input of “0” when the voltage is lower than V but only causes a negligible amount of current to go through the memory cell (regardless of the programmed state of the memory cell).

When a voltage configured to be representative of an input of either 1 or 0 as described above is applied on the memory cell, programmed to either the “1-state” or “0-state” to represent a weight of 1 or 0 as discussed above, the amount of current going through the memory cell is either the predetermined amount (representative of an output of “1”), or a negligible amount (representative of an output of “0”). Further, the input, weight and output relations satisfy the multiplication of a 1-bit input by a 1-bit weight to generate a 1-bit output in all possible variations of input and weight.

Thus, a memory cell is used to perform unsigned 1-bit to multi-bit multiplication via being programed to store a 1-bit weight, applying an input voltage to represent a 1-bit input, and to determine a 1-bit output from sensing whether the current going through the memory cell (the output current from the memory cell) is the predetermined amount.

Summation of results represented by output currents from memory cells can be implemented via connecting the currents to a common line (e.g., a local digit line or global digit line). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above. A voltage represented by a 1-bit input can be applied to the multiple memory cells separately to obtain results of unsigned 1-bit to 1-bit multiplication as described above.

In one embodiment, each memory cell has a position corresponding to its stored bit in the binary representation of the multi-bit weight. Its digitized output (e.g., from the summing of output currents from memory cells on a common line) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

Summation of results represented by output currents from sets of memory cells, each set representing a separate multi-bit weight, can be summed bitwise, via currents connected in common lines, for the different bit positions in multi-bit weights. For example, the currents from memory cells storing the least significant bit are connected to a first common line to form the summed output of results derived from the least significant bits; the currents from memory cells storing the second least significant bit are connected to a second common line to form the summed output of results derived from the second least significant bits; the currents from memory cells storing the third least significant bit are connected to a third common line to form the summed output of results derived from the third least significant bits; etc. The summed outputs can be converted to a digital form, and then shifted for summation in a digital form. Alternatively, the respective currents may be scaled prior to digitization.

In one embodiment, a memory device implements time-sliced unsigned multi-bit to multi-bit multiplication. An input represented by a binary number having a predetermined number of bits (e.g., 4 bits) can be applied one bit at a time through the same predetermined number of clock cycles (e.g., applied at time instances T0, T1, T2, etc.). Each cycle produces an output as described above for unsigned 1-bit to multi-bit multiplication.

The result of the unsigned 1-bit to multi-bit multiplication (e.g., as discussed above) obtained for each clock cycle can be shifted left according to the position of the bit of the input applied in the clock cycle. For example, the result of the clock cycle that applies the least significant bit of the input is not shifted; the result for the second least significant bit is shifted left by 1 bit; the result for the third least significant bit is shifted left by 2 bits; etc. The shifted results from the clock cycles are summed in a digital form.

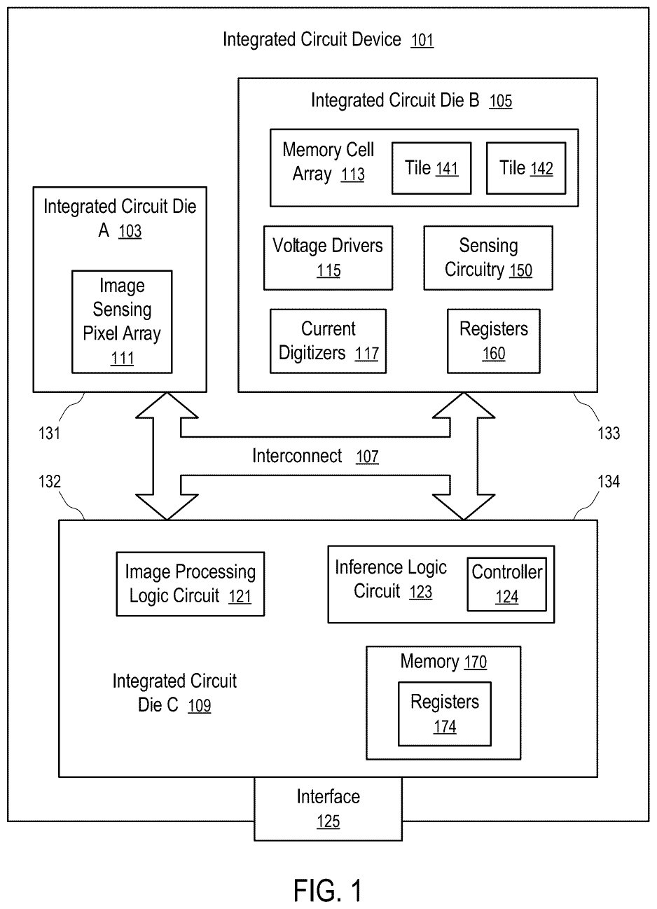

FIG. 1 shows an integrated circuit device 101 having an image sensing pixel array 111, a memory cell array 113 with tiles 141 and 142, and circuits to perform inference computations according to one embodiment. In FIG. 1, the integrated circuit device 101 has an integrated circuit die 109 having logic circuits 121 and 123, an integrated circuit die 103 having the image sensing pixel array 111, and an integrated circuit die 105 having a memory cell array 113.

In one example, memory cell array 113 includes NOR flash memory cells. The memory cells are stacked vertically in the pillars. Each transistor uses a semiconductor layer to provide a channel extending in a horizontal direction relative to the vertical pillars. Each transistor has a gate layer (e.g., ONO stack) that wraps around the outside circumference of the semiconductor layer. Wordlines (e.g., WL1, WL2) are used to apply gate voltages to the transistors. A portion of each wordline wraps around the outside circumference of the gate layer of each transistor. Isolation layers electrically separate the wordlines associated with each transistor in a given pillar. The pillars extend vertically above a semiconductor substrate. The channel extends in a horizontal direction relative to the substrate.

In one example, the integrated circuit die 109 having logic circuits 121 and 123 is a logic chip; the integrated circuit die 103 having the image sensing pixel array 111 is an image sensor chip; and the integrated circuit die 105 having the memory cell array 113 is a memory chip.

In FIG. 1, the integrated circuit die 105 having the memory cell array 113 further includes voltage drivers 115 and current digitizers 117 (e.g., accumulation circuitry to generate digital results from MVM). For example, voltage drivers 115 apply voltages to wordlines (e.g., WL1, WL2) to apply gate voltages to transistors of NOR flash memory cells.

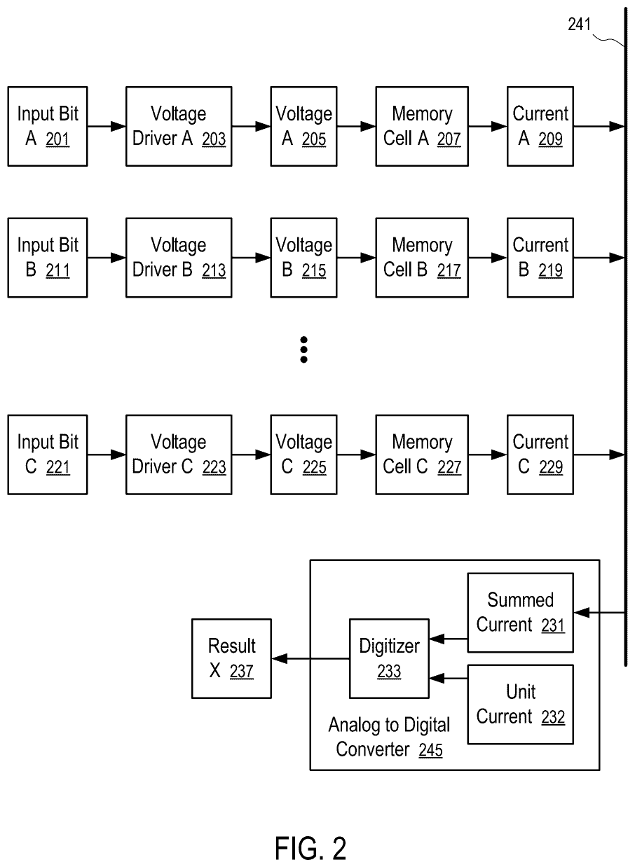

The memory cell array 113 is connected such that currents generated by the memory cells in response to voltages applied by the voltage drivers 115 are summed in the array 113 for columns of memory cells (e.g., as illustrated in FIG. 2); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

In one embodiment, sensing circuitry 150 is coupled to memory cells in tiles 141, 142. Sensing circuitry 150 is used to sense one or more characteristics of the memory cells. In one embodiment, sensing circuitry 150 includes circuitry to precharge bitlines of tiles 141, 142. Sensing circuitry 150 is configured to receive signals from controller 124 and/or read registers 160 to determine bitlines that will be disabled. In one embodiment, sensing circuitry 150 includes ADCs or other digitizers to convert sums of output currents from memory cells that are accumulated on enabled access lines (e.g., accumulated on enabled bitlines) to provide digital results (e.g., accumulation results).

The inference logic circuit 123 can be further configured to perform inference computations according to weights stored in the memory cell array 113 (e.g., the computation of an artificial neural network) and inputs derived from the image data generated by the image sensing pixel array 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either of signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding (e.g., using hybrid bonding) to provide a portion of an interconnect 107 between metal portions on the surfaces 133 and 134.

Similarly, the integrated circuit die 103 having the image sensing pixel array 111 has a bottom surface 131; and the integrated circuit die 109 having the inference logic circuit 123 has another portion of its top surface 132. The two surfaces 131 and 132 can be connected via bonding (e.g., using hybrid bonding) to provide a portion of the interconnect 107 between metal portions on the surfaces 131 and 132.

An image sensing pixel in the array 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array 111 to provide a processed image as an input to the inference computation controlled by the inference logic circuit 123. Optionally, the image processing logic circuit 121 can also use the multiplication and accumulation function provided via the memory cell array 113.

In some implementations, interconnect 107 includes wires for writing image data from the image sensing pixel array 111 to a portion of the memory cell array 113 for further processing by the image processing logic circuit 121 or the inference logic circuit 123, or for retrieval via an interface 125. The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by the image sensing pixel array 111 and processed by the image processing logic circuit 121, and retrieve results of inference computations controlled by the inference logic circuit 123.

Integrated circuit die 105 includes registers 160. Integrated circuit die 109 includes memory 170 including registers 174. In one embodiment, configuration data from a host is received via interface 125. In one example, the configuration data is data used to set registers 174 and/or 160. The configuration data corresponds to a processing step being done for a neural network. The processing includes MVM computations mapped to tiles 141, 142.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw image data from the image sensing pixel array 111, or the processed image data from the image processing logic circuit 121, or any combination thereof.

The inference logic circuit 123 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

FIG. 2 shows the computation of a column of weight bits multiplied by a column of input bits to provide an accumulation result according to one embodiment. In FIG. 2, a column of memory cells 207, 217, . . . , 227 (e.g., in the memory cell array 113 of an integrated circuit device 101) can be programmed to have threshold voltages at levels representative of weights stored one bit per memory cell.

Voltage drivers 203, 213, . . . , 223 (e.g., in the voltage drivers 115 of an integrated circuit device 101) are configured to apply voltages 205, 215, . . . , 225 to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . , 227 are connected to a common line 241 (e.g., a bitline or source line in tile 141) for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, ..., 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, . . . , 225 applied to the memory cells 207, 217, . . . , 227 are representative of digitized input bits 201, 211, . . . , 221; the memory cells 207, 217, . . . , 227 are programmed to store digitized weight bits; and the currents 209, 219, . . . , 229 are representative of digitized results.

The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

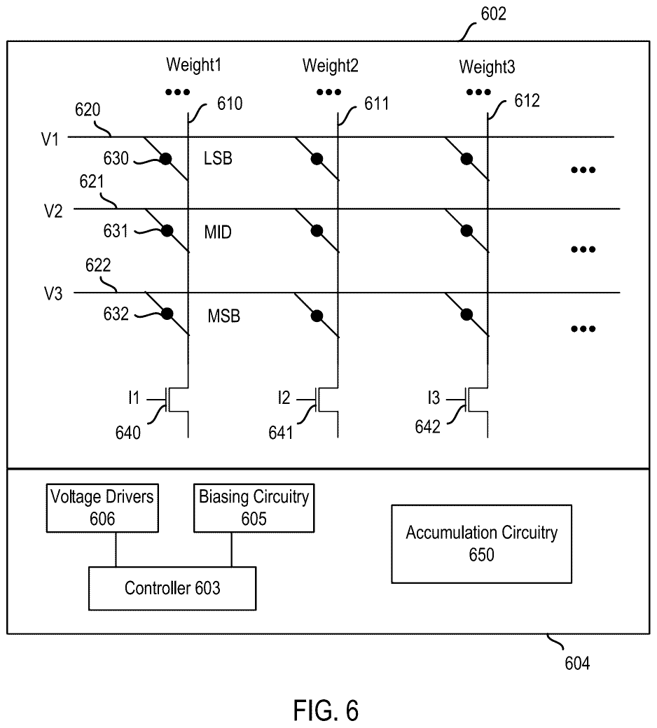

In general, a weight involving a multiplication and accumulation operation can be more than one bit. Memory cells can be used to store the different significant bits of weights (e.g., as illustrated in FIG. 6) to perform multiplication and accumulation operations. The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs.

The circuit illustrated in FIG. 2 can also be used to read the data stored in the memory cells 207, 217, . . . , 227. For example, sensing circuitry 150 can be used to sense a current associated with a memory cell. For example, to read the data or weight stored in the memory cell 207, the input bits 211, . . . , 221 can be set to zero to cause the memory cells 217, . . . , 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, . . . , 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, etc.

In general, an input involving a multiplication and accumulation operation can be more than 1 bit. For example, columns of input bits can be applied one column at a time to the weights stored in an array of memory cells to obtain the result of a column of weights multiplied by a column of inputs with results accumulated.

The multiplier-accumulator unit illustrated in FIG. 2 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIG. 2.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc. Examples of volatile memory include dynamic random-access memory (DRAM) and static random-access memory (SRAM).

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights into the memory cell array 113 and to read results from the memory cell array 113.

In some implementations, the image processing logic circuit 121 can also send commands to the interface 125 to write images into the memory cell array 113 for processing.

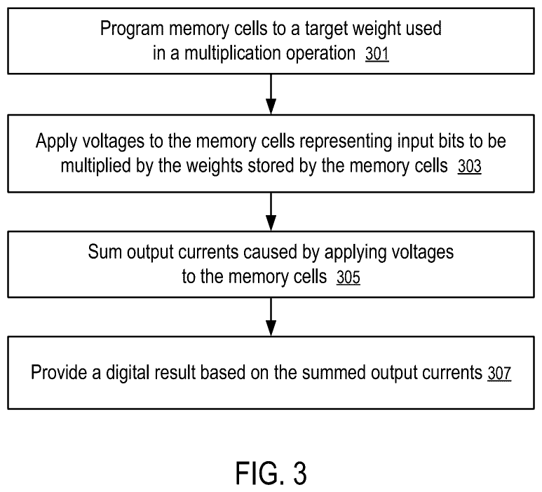

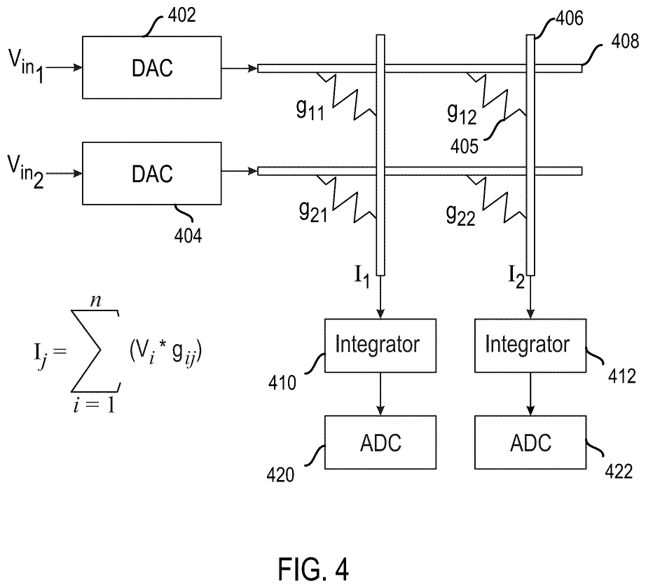

FIG. 3 shows a method of computation in an integrated circuit device based on summing output currents from memory cells according to one embodiment. For example, the method of FIG. 3 can be performed in an integrated circuit device 101 of FIG. 1 using multiplication and accumulation techniques of FIG. 2 or 4.

The method of FIG. 3 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 3 is performed at least in part by one or more processing devices (e.g., a controller 124 of inference logic circuit 123 of FIG. 1, or a local controller (not shown) of integrated circuit die 105).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 301, memory cells (or sets of memory cells such as 4-cell sets storing a bit of a signed weight) are programmed to a target weight for performing multiplication. In one example, memory cells of memory cell array 113 are programmed. In one example, memory cells 207, 206, 208 are programmed to store weights of different bit significance. The weights correspond to a multi-bit weight (e.g., Weight1 of FIG. 6).

At block 303, voltages are applied to the memory cells. The voltages represent input bits to be multiplied by the weights stored by the memory cells. In one example, voltage drivers apply input voltages 205, 215, 225.

At block 305, output currents from the memory cells caused by applying the voltages are summed. In one example, the output currents are collected and summed using line 241 as in FIG. 2.

At block 307, a digital result based on the summed output currents is provided. In one example, the summed output currents are used to generate Result X 237 of FIG. 2.

In one embodiment, some of the memory cells have a first threshold voltage programmed to represent a value of one, and the applied voltage is less than the first threshold voltage.

In one embodiment, the applied voltage is less than the first threshold voltage by at least 0.5 volts.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

FIG. 4 shows an analog weight-stationary architecture for matrix vector multiplication (MVM) according to one embodiment. Because the computational burden is largely on the MVM operation when executing a neural network, an analog weight-stationary architecture is used that focuses on the MVM operation. The other computations/logic required can generally be implemented in the digital and/or analog space since their impact on performance and energy efficiency is relatively small.

In a weight-stationary architecture, the computation is performed where the weights are stored (e.g., performed in a NAND or NOR flash memory device that stores weights). This removes or reduces the performance bottleneck and power inefficiency of moving the weights out of memory for the computation. The MVM computation is performed in the analog domain. This typically results in some computational error that does not exist in the digital domain.

The weights are stored in storage units 405 (e.g., memory cells) within the memory device (e.g., 101). The input is sent to an electrode 408 of the storage unit, resulting in a multiplication of the input and the weight (conductance of storage unit based on the stored weight) (e.g., weight of g12 multiplied by input Vin₁). Digital-to-analog converters (DAC) 402, 404 convert digital inputs into magnitudes for analog voltages used to drive electrodes 408 (e.g., an access line such as a select gate drain line).

The result is summed to another electrode (e.g., 406) (e.g., a common line 241 of FIG. 2) within the memory array and detected by an ADC 420, 422. For example, integrators 410, 412 accumulate currents I₁, I₂ from memory cells 405 determined by the conductances of the cells and provide the accumulated currents as inputs to ADC 420, 422.

In one embodiment, a memory device performs MVM on weights stored within memory cells of a three-dimensional (3D) array. Weights are stored within the memory cells. The memory cells extend vertically upwards from a semiconductor substrate (not shown). The memory cells are arranged as vertical pillars of cells.

The threshold voltage (VT) of a memory cell is set (programmed) based on the intended weight. When the cell is read with a fixed wordline voltage, the cell will sink some current (based on the cell I-V characteristics) as a function of the weight stored within the cell.

In one embodiment, a three-dimensional memory cell array has a NOR configuration with memory cells connected in parallel. The memory cell array is an example of memory cell array 113 of FIG. 1.

The array includes memory cells arranged in various vertical pillars with each cell in a pillar connected to a vertical local digit line. The array is located above a semiconductor substrate (not shown). The memory cells are also arranged as horizontal tiers. The tiers are stacked vertically.

Each of the cells is connected to a wordline that extends horizontally. Each memory cell is biased by applying a voltage to one of the wordlines and one of the local digit lines to which the cell is connected. When performing multiplication, memory cells in one or more of the tiers are selected by applying a voltage to wordlines.

Each local digit line of a pillar is connected to a global digit line using a select transistor. When performing multiplication, output currents from the selected memory cells of a tier(s) are accumulated on global digit lines. In some embodiments of a resistive array, multiple tiers can be selected at the same time for computation.

In one embodiment, each of the memory cells is programmed to store a weight bit for performing multiplication. For the selected tier of memory cells that will be used for multiplication, a voltage is applied on the wordline of each cell so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors using select lines (e.g., SL−, SL+). Output currents from the memory cells are then summed on global digit lines and a digital result provided, such as discussed above.

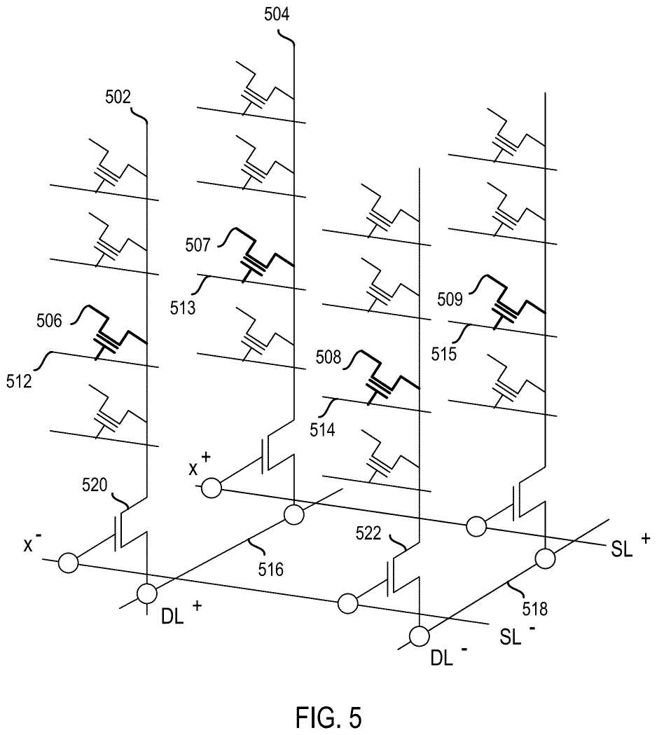

FIG. 5 shows a three-dimensional memory cell array having floating gate memory cells in a NOR configuration according to one embodiment. The memory cells are connected in parallel. The memory cell array illustrated in FIG. 5 is an example of memory cell array 113.

Similarly as discussed above, the memory cells can be arranged in horizontal tiers. One or more of the tiers is selected for performing multiplication. For example, memory cells 506, 507, 508, 509 are selected by applying a gate voltage to each cell. The voltage is applied using wordlines 512, 513, 514, 515.

In one embodiment, wordlines 512 and 514 are connected as a single line. Wordlines 513 and 515 are also connected as a single line.

The memory cells of the array are arranged in pillars each having a vertical local digit line 502, 504. Each local digit line is coupled to a global digit line 516, 518 by select transistors 520, 522.

In one embodiment, each of the memory cells is programmed to store a weight bit for performing multiplication. For the selected tier of memory cells that will be used for multiplication, a voltage is applied on the wordline so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 520, 522 using select lines (SL). Output currents from the memory cells are then summed on global digit lines 516, 518, and a digital result provided, such as discussed above.

Various memory cell implementations can be used for performing signed multiplication. In one embodiment, the signed multiplication is performed in a so-called four-quadrant system, in which each of an input and a weight to be multiplied can have a positive or negative sign. For example, some neural network models make use of matrix vector multiplication in which the weights of the model are signed. In one example, resistive random-access memory (RRAM) cells are used. In one example, NAND or NOR flash memory cells are used.

In one embodiment, matrix vector multiplication is performed using stored weights. Input signals are multiplied by the weights to provide a result. In one example, the weights are determined by training a neural network model. The model uses both positive and negative values for the weights. In one example, the weights are stored in memory cells of memory cell array 113 of FIG. 1. In one example, the model is trained using image data, and the trained model provides inference results based on inputs from an image sensor.

In one embodiment, a multiplier accumulator unit uses signed multiplication. Weights may be represented by multi-bit values (e.g., 8-64 bits). An extra bit is used to represent the sign of a weight value. For example, a system may use 8 bit signed weights, where values of the weights are represented by seven bits, and the eighth bit is used to represent the sign. An extra bit can be used in a similar manner for signed inputs.

In one embodiment, a signed 1-bit number (e.g., an input and/or weight) has one of three possible values: −1, 0, 1. For example, a signed weight can be represented by a 2-bit number, where a 2-bit value of 01 represents a signed 1-bit value of −1; a 2-bit value of 00 represents a signed 1-bit value of 0; and a 2-bit value of 10 represents a signed 1-bit value of +1. The 2-bit value of 11 is not used. In other examples, the various combinations of the 2 bits can represent different signed values, as may be desired for a given implementation.

In one example, a controller that controls multiplications manages the two bit values by keeping track of the meaning represented by each bit (e.g., sign or magnitude). In one example, the controller is part of inference logic circuit 123 of FIG. 1. 1-bit by 1-bit multiplications of the two-bit numbers representing the signed 1-bit input and the signed 1-bit weight can be configured to produce a result for signed 1-bit to 1-bit multiplication. In one example, the result has been determined in response to a request from a host system over interface 125 of FIG. 1. In one example, the signed inputs used to produce the result are based on data collected by image sensing pixel array 111 of FIG. 1.

In one embodiment, a two-cell implementation is used for signed 1-bit to 1-bit multiplication. Two memory cells of a set are used to store the two bits of the signed 1-bit weight in the two-bit representation.

Two input lines are used to apply the two bits of the signed 1-bit input (two-bit representation) (sometimes referred to herein as a “positive version”) at a first time instance (e.g., a first clock cycle, T0), and then a negative version of the input at a second time instance (e.g., a second clock cycle, T1).

In one embodiment, a four-cell implementation is used for signed 1-bit to 1-bit multiplication. Four memory cells of a set are used to store the two bits of the signed 1-bit weight in the two-bit representation (sometimes referred to herein as a “positive version”) and also in a negative version of the two-bit representation. Two input lines are used to apply the two bits of the signed 1-bit input (two-bit representation).

In one example, the input lines provide voltages to a memory cell set. The set has four memory cells. In one example, the input lines can be wordlines, bitlines, or select gate lines (SL or SGD), depending on type of memory cell and the particular set configuration (e.g., memory cells arranged in series as for NAND flash versus memory cells arranged in parallel as for RRAM or NOR).

The first pair of memory cells is multiplied by the signed input. The output currents are summed on a first line. The second pair of memory cells is also multiplied by the signed input. The output currents are summed on a second line.

The bit result (e.g., 0 or 1) for the first line provides the first bit of the signed 1-bit to 1-bit multiplication (two-bit representation). The bit result (e.g., 0 or 1) for the second line provides the second bit of the signed 1-bit to 1-bit multiplication (two-bit representation). In one example, these first and second bit results provide a 1-bit signed result.

In one example, an image is provided as an input to a neural network. The neural network includes convolution layers. The size of each layer varies. For example, each layer has a different number of features and neurons. For example, one layer uses a smaller number of filters than another layer. The neural network provides a final result. In one example, the final result is a classification of an object represented by the image.

When performing computations, matrix vector multiplication operations are mapped to tiles in a memory cell array (e.g., 113). For example, this mapping involves identifying portions of the memory cell array that are to be used during the computation for a particular layer. This mapping typically varies as computations progress from one layer to another.

In one example, the image is data obtained from image sensing pixel array 111. In one example, weights for the neural network have been programmed into memory cells of tiles 141, 142. In one example, a different memory array configuration is used for each layer as computations progress from one layer to another.

In one example, tiles of a memory device are configured to be partially filled for performing a multiplication or other operation for a neural network. The tiles are in a memory cell array (e.g., 113). In one example, the array includes about 1,500 NAND or NOR tiles. The tiles are filled (programmed) with weights for neurons to be used (e.g., used for at least one layer). The particular weights that are valid for a given MVM computation will vary, as discussed above.

In one embodiment, a NAND or NOR memory device has a register that is exposed to a host interface. The host can set registers to configure the NAND or NOR device (e.g., a parameter can be defined by the host). For example, the NAND or NOR device can provide fixed options to the host of certain predefined neuron sizes. The host can select one of the predefined neuron sizes that is closest to the size of the current computation. The NAND or NOR device uses logic circuitry to set the configuration based on the definition by the host of the predefined neuron size.

In one embodiment, the host or local controller communicates the neuron size in a register. In one embodiment, the NAND or NOR device selects one of the predefined neuron sizes above based on the neuron size stored in the register.

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate. As an example, 512 memory cell sets are coupled to the line(s). Inputs are provided using 512 pairs of select lines (e.g., SL+, SL−), with one pair used per set. The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second digit lines.

A first digital value (e.g., an integer) representing the current on the first digit line is determined as the multiple of a predetermined current (e.g., as described above) representing 1. A second digital value representing the current on the second digit line is determined as the multiple of the predetermined current. The first and second digital values are, for example, outputs from a digitizer(s).

In one embodiment, a memory device includes a memory cell array having sets of NOR flash memory cells (e.g., using memory cell array 113). Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice. In one example, input bits are applied serially one at a time.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then left shifting is not required when adding the signed results (e.g., first, second, third, and fourth signed results) to obtain a signed accumulation result. Instead, the signed results can be added directly without left shifting.

In one embodiment, a memory device performs analog summation of 1-bit result currents having different bit significance implemented via different bias levels. A memory cell (e.g., a RRAM cell or NOR flash memory cell) can be programmed to have exponentially increased (e.g., increasing by powers of two) current for different bias levels.

In one embodiment, a memory cell can be programmed to have a threshold with exponentially increased current for higher bias/applied voltage. A first voltage can be applied to the memory cell to allow a predetermined amount of current (indicated as 1×) to go through to represent a bit value of 1 for the least significant bit.

To represent a bit value of 1 for the second least significant bit, a second voltage can be applied to the memory cell to allow twice (indicated as 2×) the predetermined amount of current to go through, which is equal to the predetermined amount of current multiplied by the bit significance of the second least significant bit.

The memory cell can be similarly biased to have a higher amount of current equal to the predetermined amount of current multiplied by the bit significance of the bit when the bit value is 1.

When different voltages are applied to memory cells each representing one bit in a number such that the respective bit significance of each cell is built into the output currents as described above, the multiplication results involving the memory cells can be summed via connecting them to a line without having to convert the currents for the bits separately for summation.

For example, a 3-bit-resolution weight can be implemented using three memory cells. Each memory cell stores 1-bit of the 3-bit weight. Each memory cell is biased at a separate voltage level such that if it is programmed at a state representing 1, the current going through the cell is a base unit times the bit significance of the cell. For example, the current going through the cell storing the least significant bit (LSB) is a base unit of 25 nA, the cell storing the middle bit (MID) 2 times (2×) the base unit (50 nA), and the most significant bit (MSB) 4 times (4×) the base unit (100 nA).

In one embodiment, a solid-state drive (SSD) or other storage device uses a memory cell array having memory cells. In one example, resistive random-access memory (RRAM) cells are used. In one example, NAND or NOR flash memory cells are used.

In one embodiment, each memory cell is programmable to store one bit of a multi-bit weight. After being programmed, voltage drivers apply different voltages to bias the memory cells for use in performing multiplication. Inputs to be multiplied by the multi-bit weights can be represented by a respective input pattern applied to select gates of select transistors coupled to the memory cells (e.g., as described above), or by varying the different voltages between a fixed voltage state representing an input bit of 1 and a zero state representing an input bit of 0.

One or more common lines are coupled to the memory cells. The lines receive one or more output currents from the memory cells (e.g., as described above). Each common line (e.g., digit line or bitline) is used to accumulate the currents to sum the output currents.

In one embodiment, three memory cells store values representing three bits of a stored weight. One bit is for an MSB, one bit is for a bit of middle significance (sometimes indicated as “MID” herein), and one bit is for an LSB. This provides a multi-bit representation for the stored weight.

FIG. 6 shows an architecture having resistive random access memory (RRAM) or NOR memory cells arranged in a memory cell array 602 in a parallel configuration for performing multiplication (e.g., MVM) according to one embodiment. For example, memory cells 630, 631, 632 store bits of respective significance for a multi-bit weight (indicated as Weight1). A simple 3-bit weight is illustrated, but a larger number of bits can be stored for each weight. When performing multiplication, each of memory cells 630, 631, 632 can be accessed in parallel. In one example, memory cell array 602 includes memory cells arranged as illustrated in FIG. 9.

Each memory cell provides an output current that corresponds to a significance of a bit stored by the memory cell. Memory cells 630, 631, 632 are connected to a common line 610 for accumulating output currents. In one example, line 610 is a bitline.

Different voltages V1, V2, V3 are applied to memory cells 630, 631, 632 using wordlines 620, 621, 622. Voltages are selected so that the output currents vary by a power of two based on bit significance, for example as described above.

In one embodiment, an input signal I1 is applied to the gate of select transistor 640. Select transistor 640 is coupled to common line 610. An output of select transistor 640 provides a sum of the output currents. In one embodiment, when the input signal is applied to the gate of select transistor 640, the different voltages V1, V2, V3 are held at a constant voltage level.

In an alternative embodiment, an input pattern for multiplication by Weight1 can be applied to wordlines 620, 621, 622 by varying the different voltages V1, V2, V3 between fixed voltages and zero voltages similarly as described above to represent input bits of 1 or 0, respectively.

Memory cell array 602 is formed above semiconductor substrate 604. In one embodiment, memory cell array 602 and semiconductor substrate 604 are located on different chips or wafers prior to being assembled (e.g., being joined by bonding).

Similarly, as described above for Weight1, multi-bit weights Weight2 and Weight3 can be stored in other memory cells of memory cell array 602, and output currents accumulated on common lines 611, 612, as illustrated. These other memory cells can be accessed using wordlines 620, 621, 622. Common lines 611, 612 are coupled to select transistors 641, 642, which each provide a sum of output currents as an output. Input patterns I2, I3 can be applied to gates of the select transistors. Additional weights can be stored in memory cell array 602.

Output currents from common lines 610, 611, 612 are accumulated by accumulation circuitry 650. In one embodiment, accumulation circuitry 650 is formed in semiconductor substrate 604 (e.g., formed at a top surface).

In one embodiment, voltage drivers 606 and biasing circuitry 605 are formed in semiconductor substrate 604. Logic circuitry (not shown) formed in semiconductor substrate 604 is used to implement controller 603. Controller 603 controls voltage drivers 606 and biasing circuitry 605.

In one embodiment, voltage drivers 606 provide the different voltages V1, V2, V3. Biasing circuitry 605 applies inputs I1, I2, I3.

Various embodiments related to memory devices using unary coding to store weights are now described below. In some embodiments, the variability of a synaptic array of memory cells (e.g., chalcogenide cells or RRAM cells) is reduced during a synaptic sum of products operation. For example, the variability can be reduced to equivalent levels as observed for a 3D NAND-based synaptic array. The generality of the following description is not limited by the various embodiments described above.

Memory cell technologies used in some memory arrays can cause the technical problem of excessive noise. For example, due to the physics of cell conduction, a chalcogenide memory cell (e.g., in vertical or planar 3D arrays) operating in a sub-threshold region is intrinsically noisier than a NAND cell. In addition, for analog accumulation of currents (e.g., matrix vector multiplication), the cell is required to operate in the subthreshold region (below the snapback level of the cell) where its subthreshold slope is relatively high. In contrast, a NAND memory cell (e.g., in a 3D array) can be moved along its IV curve to operate in a less steep region of the curve. As a result, the overall variation of an individual chalcogenide cell is typically larger than that of a NAND cell. This leads, for example, to a larger error rate during MVM computation (e.g., an L2 error rate representing a measure of the fidelity of computing the MVM using the memory array versus an ideal computation).

To address this and other technical problems, at least some embodiments use a parallel (NOR) configuration of memory cells. For example, chalcogenide cells are arranged vertically within a pillar. Certain characteristics of chalcogenide cells support reduced noise. For example, the density of these cells is higher, and the resistance of the pillars used is lower as compared to a series (NAND) configuration of memory cells with the high pillar resistance of a 3D NAND array structure.

In one example, the NOR configuration enables definition of a synaptic unit or synapse with multiple cells such that the combined output current of the cells is able to match the noise performance and compute density of an equivalent 3D NAND-based synaptic array. In some cases, noise reduction is further promoted by using a cell placement algorithm that performs multiple loops of programming, measuring output current, and further programming based on measured output currents.

In one embodiment, a NOR memory array stores weights using unary coding. A controller performs matrix vector multiplication using the weights. Each weight is represented by a respective unary code. The unary coding is based on a number of memory cells programmed to provide a unit current (e.g., 4 nA) as an output. The NOR memory array includes memory cells vertically configured in pillars that are used to store the weights. Each memory cell is a phase change memory cell (e.g., chalcogenide cell) or a resistive random access memory (RRAM) cell.

In one embodiment, the NOR array has synapses, each synapse including memory cells arranged in tiers. Each synapse uses a four-quadrant configuration. A controller programs the memory cells of each synapse to represent a respective weight using unary coding. Multiplication is performed by accumulating output currents from the programmed memory cells. The memory cells are vertically arranged in pillars. Each synapse uses four pillars of cells. The array is formed over a semiconductor substrate. In each pillar, the memory cells are arranged vertically along a bitline extending above the substrate.

In one embodiment, a NOR memory array has memory cells that store weights using unary coding. A controller programs the cells to place a subthreshold current of each memory cell in a target range and/or to target a unit output current (e.g., to target a unit output current of 4 nA+/−0.5 nA). The controller places the subthreshold current by programming each memory cell, measuring an output current of the memory cell, and applying at least one write pulse to the memory cell based on the measured output current. For example, applying write pulses to the memory cells in multiple programming loops reduces a standard deviation of a distribution of output currents for the memory cells.

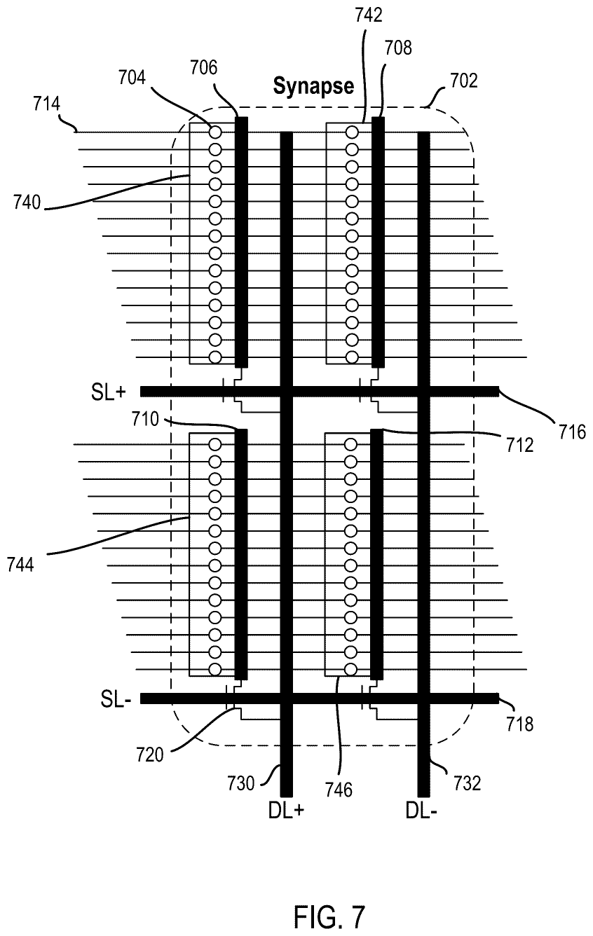

FIG. 7 shows a four-quadrant implementation of a synapse 702 according to one embodiment. Synapse 702 includes four pillars 740, 742, 744, 746. FIG. 7 is a flattened electrical representation of synapse 702. In an actual device, the pillars extend vertically out of the plane of the figure.

Each pillar includes memory cells 704. For example, each pillar includes 14 memory cells programmed to store representations of weights using 2× unary coding. 2× unary coding as used herein refers to coding in which the unary code is applied twice, thus requiring twice the number of cells of 1× unary coding for the same stored value. The memory cells are electrically connected to bitlines 706, 708, 710, 712 that run vertically in each pillar.

Wordlines 714 electrically connect to each memory cell 704. During multiplication, wordlines 714 are biased by bias circuitry to a fixed voltage bias.

Select lines 716, 718 are used to bias the gates of select transistors 720 (sometimes referred to as selectors) that electrically connect each bitline to one of digit lines 730, 732. During multiplication, input signals are provided using select lines 716, 718. Output currents from memory cell 704 accumulated from the bitlines onto the digit lines. The accumulated current collected by digit lines 730, 732 is converted by accumulation circuitry into a digital result. In one example, the digital result is an output of an analog to digital converter having the accumulated current as an input.

Synapse 702 is formed above a semiconductor substrate (not shown). The pillars and bitlines extend vertically above the semiconductor substrate. The select lines and digit lines run horizontally above the semiconductor substrate and orthogonally to the pillars and bitlines. The wordlines also run horizontally above a semiconductor substrate and are organized in tiers running vertically up and down each pillar.

In one example, a memory device is built using synapse arrays. Each synapse array is formed using a structure having 512 by 512 pillars. For example, a memory device has four 512×512 pillar arrays. Each pillar has 64 tiers with 2 cells per tier for a total of 128 memory cells per pillar. This provides room for 9 synaptic layers configured in the 64 tiers.

In one example, 2× unary coding is used to program the memory cells. Each synapse includes 56 cells. The synapse includes four pillars with each pillar having 14 cells. Each cell programmed to logic one state provides a unit output current (e.g., 4 nA). The memory cells can be enabled in pairs. In one example, a +7 weight is represented by 14 cells that are each programmed to a logic one (1) state. During multiplication, these 14 cells provide total output current of 56 nA, which is accumulated on a digit line.

In one example, characteristics of chalcogenide memory cells are used to advantage. The chalcogenide cell conducts less current and has more cells available per pillar than equivalent NAND memory cell approaches (e.g., by at least 2×). These characteristics are leveraged to reduce combined synaptic variation by use of unary coding.

For example, 3 bits of weight resolution can be mapped to 7 distinct memory cells using unary coding. For even more noise resilience, 3 bits of resolution can be mapped to 14 cells using 2× unary coding. Each cell's state (e.g., threshold) can be programmed to provide a unit of current (e.g., a logic 1 bit per cell) at a fixed common bias across the cell. For example, the fixed common bias is provided by applying a fixed voltage to wordlines 714. In order to support a synapse for four-quadrant multiplication, four times the number of cells are required: 28 cells per synapse in 4 distinct pillars for 1× unary coding, or 56 cells for 2× unary coding.

Unary coding (and other variants) enable reduced total synaptic current variation by virtue of averaging the random variations of individual cells when their currents are combined (e.g., accumulated from multiple bitlines using a common digit line). For example, 1× unary coding can be sufficient to reduce the overall synaptic variation in order to achieve acceptable L2 error metrics for MVM operation.

In one embodiment, for each synapse, memory cells can be dispersed in separate tiles. For example, this can be done for a four-quadrant implementation with one tile for each quadrant of the synapse.

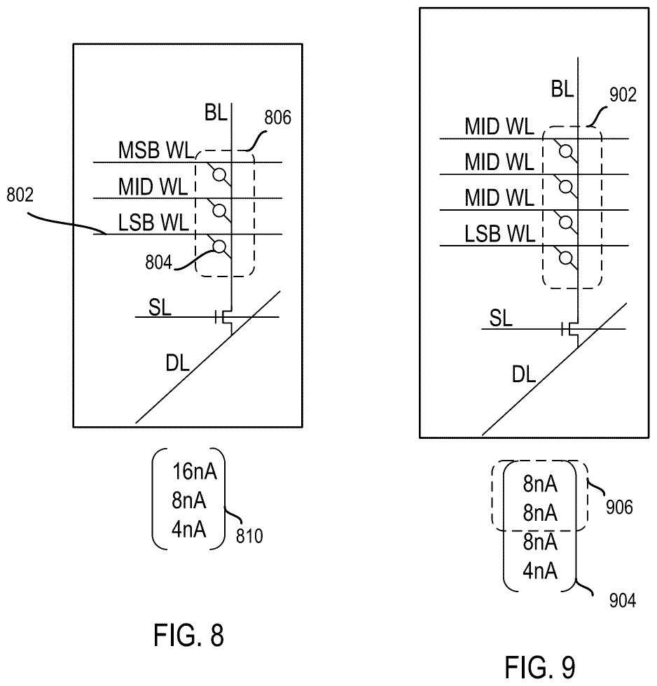

FIGS. 8-9 show pillars having memory cells that store weights using bits of varying significance according to some embodiments. In the unary coding described above, each memory cell stores a single bit. In one example, a four-quadrant configuration uses 28 cells per synapse for 1× unary coding, and 56 cells per synapse for 2× unary coding. Each bit has a common significance (e.g., each bit is a least significant bit (LSB)). In alternative embodiments as shown in FIGS. 8-9, memory cells used in pillars can store bits having varying significance. In yet other embodiments, a single memory cell can be used to store multiple bits per cell (e.g., MLC memory arrays).

FIG. 8 shows a pillar including synapse 806. Memory cells 804 are electrically connected to bitline BL. During multiplication, each memory cell can provide an output current 810 that corresponds to a significance of the cell (e.g., MSB, MID, LSB, as illustrated). The output currents can vary by powers of two. For example, the most significant bit output current is four times greater than the least significant bit output current. In one example, the varying output current is achieved by varying the voltage applied to wordlines 802. In one example, the varying output current is achieved by varying a characteristic of the memory cell (e.g., threshold voltage). In one example, a four-quadrant configuration uses 12 cells per synapse.

FIG. 9 shows a pillar including synapse 902. Memory cells provide output currents 904 corresponding to MID and LSB significance. The output currents 906 from two MID significance memory cells can be used to correspond to the output current from a single MSB cell. In this case, the unary code is applied to only the MSB cells in the synapse (using the two MID cells to represent the value of one MSB cell). In one example, a four-quadrant configuration uses 16 cells per synapse.

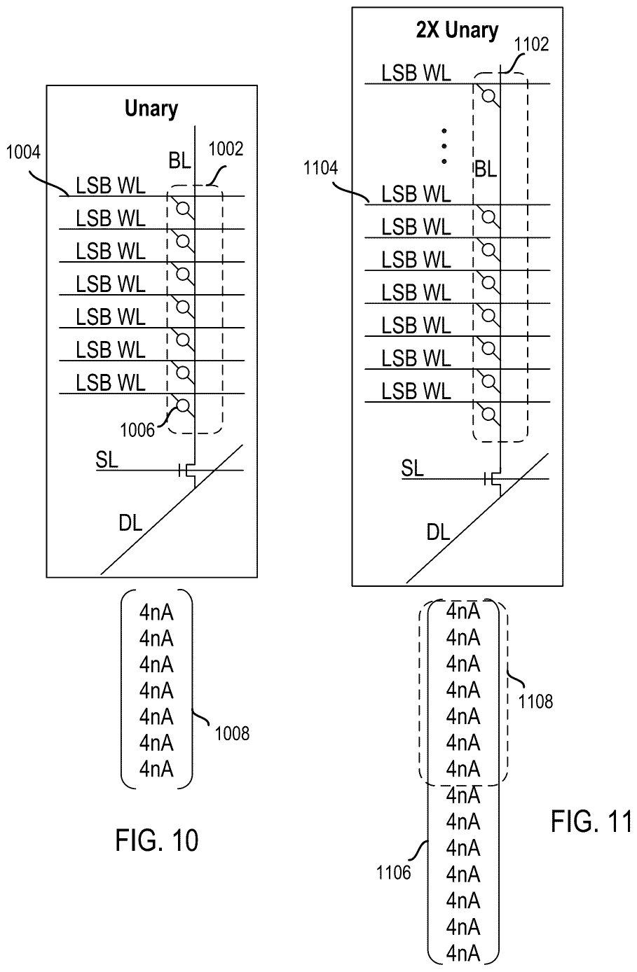

FIG. 10 shows a pillar having memory cells that store weights using unary coding according to one embodiment. For example, a single pillar can store multiple weights in vertical portions along the pillar. For example, portion 1002 of the pillar includes seven memory cells 1006 used to store a weight represented by unary coding.

Wordlines 1004 are used to bias the memory cells 1006 and are illustrated as being grouped together. In some cases, there can be inactive wordline tiers intermixed with the active selected wordline tiers. Also, wordline tiers corresponding to a single weight can be dispersed along the pillar amongst wordline tiers for other weights.

A fixed voltage bias is applied to the memory cells using wordlines 1004 during multiplication. An input signal is provided on select line SL. Output currents 1008 are accumulated from the memory cells by digit line DL. For example, the number of memory cells 1006 that are programmed to a logic one state (e.g., provide an output current of 4 nA) corresponds to the value of the stored weight.

In one example, a unary coded synapse is able to achieve equivalent Tera Operations per second per Watt (TOPS/W) and TOPS/mm² performance as achieved for comparable 3D NAND synapses. The total weight density is reduced for the same number of tiers. Also, unlike 3D NAND, chalcogenide memory cell technology allows for more tiers due to its lower pillar resistance.

Unary coding requires enabling multiple memory cells. When enabling multiple chalcogenide cells, the noise from each cell tends to cancel out one another. In other words, the noise averages out. In one example, with a sufficient number of chalcogenide cells being used, the noise performance can match that of a single NAND cell.

In one embodiment, an input for a multiplication is provided on select line SL. The wordlines are selected/enabled for working on a specific set of tiers. The wordlines are static and do not change as the input varies. Then, when done with the multiplication, a controller can disable this set of wordlines and enable another set of wordlines (e.g., for a different synapse). The representation of the weight stored by each synapse is based on how each memory cell in the synapse has been programmed, whether conducting (e.g., logic one) or non-conducting (e.g., logic zero).

FIG. 11 shows a pillar having memory cells that store weights using 2× unary coding according to one embodiment. For example, portion 1102 of the pillar includes 14 memory cells storing a weight using 2× unary coding.

During multiplication, a fixed voltage bias is applied to wordlines 1104. The memory cells provide output currents 1106 when programmed to a logic one state. Currents 1108 are additional currents relative to output currents for the 1× unary coding approach.

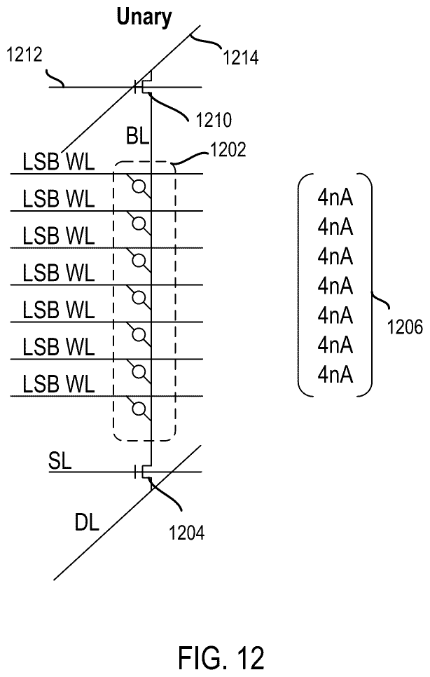

FIG. 12 shows a pillar having top and bottom select transistors according to one embodiment. Portion 1202 of the pillar includes seven memory cells storing a weight represented using 1× unary coding. Select transistor 1204 electrically connects bitline BL to digit line DL for accumulating unit output currents 1206 from the memory cells. An input signal for multiplication is applied to select line SL.

Select transistor 1210 connects bitline BL to an access line 1214. Access line 1214 is used, for example, for programming the memory cells. Select line 1212 is used to control select transistor 1210. During programming, for example, bias circuitry can apply voltages to access line 1214.

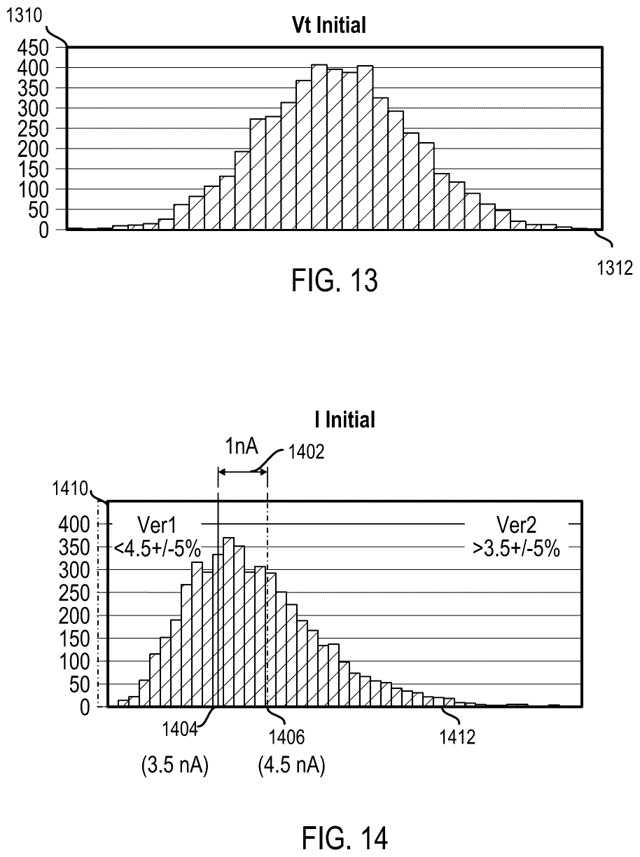

FIG. 13 shows an exemplary memory cell distribution of initial threshold voltages (e.g., for memory cells 1006). A number 1310 of memory cells is shown on the vertical axis, and an initial threshold voltage 1312 for a memory cell is shown on the horizontal axis. For example, the distribution of initial threshold voltages is provided after an initial programming of the memory cells (e.g., chalcogenide cells).

FIG. 14 shows an exemplary memory cell distribution of initial output currents. A number 1410 of memory cells is shown on the vertical axis, and an initial output current 1412 from a memory cell shown on the horizontal axis. The output current distribution of FIG. 14 corresponds to the initial threshold voltage distribution of FIG. 13. In one example, the output current is a subthreshold current from a chalcogenide memory cell.

For example, after the initial programming of the memory cells, a controller determines whether an output current for each memory cell falls within a target current range 1402. If the output current is greater than upper current limit 1406, or less than lower current limit 1404, then one or more write pulses are applied to the memory cell to change the output current. The output current of each memory cell is measured again to determine if the output current falls within target range 1402. If not, then additional programming loops are repeated as necessary by applying write pulses anytime the measured output current falls outside of range 1402.

In one embodiment, the same write pulse is repeated over and over until write bounce (sometimes referred to as program noise or write noise) places the subthreshold current in the target output current range. Program noise or write noise relates to a stochastic component in the program operation that can cause a memory cell/bit to end up in a slightly different state under the same nominal programming conditions. Usually, the program noise is viewed in contrast with read noise. Read noise relates to the observation that the same bit, read several times after one single program operation, can appear in slightly different states, due to small fluctuations of its internal state variables (e.g., the state of the traps in a dielectric film, which can fluctuate between empty and filled because of thermal noise or other effects).

It is desirable to separate program noise from read noise, because if a controller does a single program operation followed by a single read operation, the controller does not know how much the memory cell state has been influenced by program noise versus read noise. In one embodiment, the controller uses sequences of repeated program and read operations to statistically separate the effects on the memory cell of these two components.

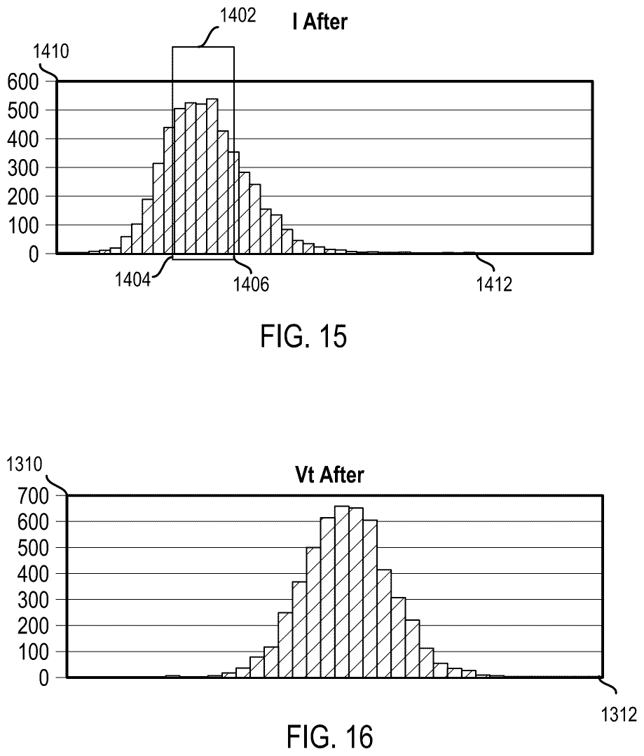

FIG. 15 shows an exemplary memory cell distribution of output currents after performing multiple programming loops according to one embodiment. After performing the current measurement and write pulse application described above for multiple loops (e.g., greater than 10-30 loops), the output current distribution narrows (e.g., the standard deviation is reduced) as illustrated in FIG. 15.

FIG. 16 shows an exemplary memory cell distribution of threshold voltages after performing multiple programming loops according to one embodiment. The threshold voltage distribution of FIG. 16 corresponds to the output current distribution of FIG. 15. After performing the current measurement and write pulse application loops described above, the threshold voltage distribution narrows (e.g., the standard deviation is reduced) as illustrated in FIG. 16.

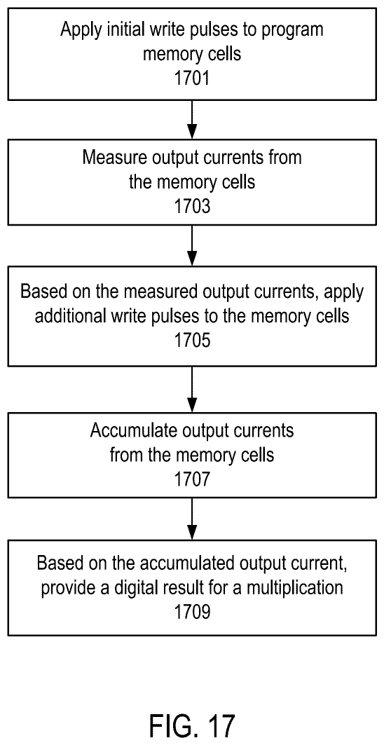

FIG. 17 shows a method for programming memory cells used to perform multiplication by accumulating output currents according to one embodiment. For example, the method of FIG. 17 can be performed in integrated circuit device 101 of FIG. 1 when performing multiplication (e.g., as described in various embodiments above).

The method of FIG. 17 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 17 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1701, initial write pulses are applied to program memory cells. In one example, memory cells 1006 are programmed using unary coding. In one example, memory cells are programmed to target an output current falling within range 1402.

At block 1703, output currents from the memory cells are measured. In one example, controller 603 uses sensing circuitry to measure the output currents.

At block 1705, based on the measured output currents, additional write pulses are applied to the memory cells. In one example, multiple loops of measurement and applying write pulses are used until each memory cell has a measured output current that falls within target range 1402.

At block 1707, multiplication is performed by accumulating output currents from the programmed memory cells. In one example, the multiplication is matrix vector multiplication. In one example, the output currents are accumulated using digit lines 730, 732.

At block 1709, the total accumulated output current is used to provide a digital result for the multiplication. In one example, accumulation circuitry 650 is used to accumulate the output current and provide the digital result. In one example, analog-to-digital converter 245 is used to provide the digital result.

In some aspects, the techniques described herein relate to a system including: a memory array configured to store a plurality of weights using unary coding (e.g., 1006); and at least one controller configured to perform matrix vector multiplication using the weights.

In some aspects, the techniques described herein relate to a system, wherein each weight is represented by a respective unary code.

In some aspects, the techniques described herein relate to a system, wherein the unary coding is based on a number of memory cells programmed to provide a unit current as an output.

In some aspects, the techniques described herein relate to a system, wherein the memory array includes memory cells configured to store the weights, and each memory cell is a phase change memory cell (e.g., chalcogenide cell) or a resistive random access memory cell.

In some aspects, the techniques described herein relate to a system, further including wordlines (e.g., 1004, 1104) connected to first memory cells storing the weights, wherein the controller is further configured to select the first memory cells by applying a fixed bias to the wordlines.

In some aspects, the techniques described herein relate to a system, wherein the weights are stored in synapses, and each synapse uses a four-quadrant configuration (e.g., 702).

In some aspects, the techniques described herein relate to a system, wherein the memory array includes a plurality of tiles, and each quadrant of each synapse is configured in a separate tile.

In some aspects, the techniques described herein relate to a system, further including accumulation circuitry configured to accumulate output currents from memory cells of the memory array that store the weights.

In some aspects, the techniques described herein relate to a system, wherein the accumulation circuitry includes an analog-to-digital converter to convert the accumulated output currents to a digital output.

In some aspects, the techniques described herein relate to an apparatus including: a plurality of synapses (e.g., 702), each synapse including memory cells; and at least one controller configured to: program the memory cells of each synapse to represent a respective weight using unary coding; and accumulate output currents from the memory cells.

In some aspects, the techniques described herein relate to an apparatus, wherein each synapse uses a four-quadrant configuration.

In some aspects, the techniques described herein relate to an apparatus, wherein the memory cells are arranged in at least two pillars (e.g., 740, 742, 744, 746).

In some aspects, the techniques described herein relate to an apparatus, further including a semiconductor substrate, wherein the memory cells are arranged vertically along a bitline (e.g., 706, 708) extending above the substrate.

In some aspects, the techniques described herein relate to an apparatus, wherein a number of the memory cells programmed to a conducting state corresponds to a unary code.

In some aspects, the techniques described herein relate to an apparatus, further including wordlines (e.g., 714) vertically stacked in tiers above a semiconductor substrate, wherein each wordline is configured to apply a fixed bias to one of the memory cells.

In some aspects, the techniques described herein relate to an apparatus, further including a bitline, wherein each of the memory cells has a terminal connected to the bitline.

In some aspects, the techniques described herein relate to an apparatus, further including a digit line (e.g., 730, 732) and a select transistor (e.g., 720), wherein the bitline is coupled to the digit line using the select transistor.

In some aspects, the techniques described herein relate to an apparatus, wherein the controller is further configured to perform a multiplication of an input by at least one weight stored in the synapses, and the input is applied to a gate of the select transistor.

In some aspects, the techniques described herein relate to an apparatus, wherein each of the memory cells corresponds to a least significant bit (LSB).

In some aspects, the techniques described herein relate to an apparatus, wherein at least one of the memory cells (e.g., 804) corresponds to a least significant bit (LSB) having a unit output current, and at least one of the memory cells corresponds to a most significant bit (MSB) having an output current that is a power of two multiple of the unit output current.

In some aspects, the techniques described herein relate to a device including: a plurality of memory cells configured to store weights using unary coding; and at least one controller configured to place a subthreshold current of each memory cell in a target range (e.g., 1402).

In some aspects, the techniques described herein relate to a device, wherein placing the subthreshold current includes programming each memory cell, measuring an output current of the memory cell, and applying at least one write pulse to the memory cell based on the measured output current.

In some aspects, the techniques described herein relate to a device, wherein applying write pulses to the memory cells reduces a standard deviation of a distribution of output currents for the memory cells.

In some aspects, the techniques described herein relate to a device, wherein the controller is further configured to perform multiplication by accumulating output currents from the memory cells.

Various embodiments related to updating weights on a memory device during training of a neural network are now described below. The generality of the following description is not limited by the various embodiments described above.

Efficient training in an analog neural network array requires the ability to update the weight of synaptic connections in the array in a massively parallel manner. This implies that a gradual adjustment of each synapse weight be provided along with a way to both increment and decrement the synaptic weights.

At least some embodiments described below address the above technical need by enabling parallel updates during the training phase of a neural network array of memory cells. The memory cells are arranged in a NOR configuration along a pillar, and selection of tiers from the pillar is randomized. The parallel (NOR) configuration array of memory cells (e.g., chalcogenide cells) enables selection of multiple cells along the pillar while accumulating currents from these cells. In contrast, this is not possible with a 3D NAND array due to its use of series connections of memory cells.

Parallel and gradual updates to the states of the memory cells in the NOR array is done by mapping the synaptic cells to a large number of tiers in the array and randomizing the selection of the tier or tiers for each update event (e.g., during training). The cells are updated by applying one or more write pulses in a direction of change that allows a gradual increment of the cell resistance (change in cell threshold voltage). In one embodiment, positive and negative synaptic weight updates are enabled by selecting bitline BL and wordline WL electrodes in accordance with the synapse definition for 4-quadrant operation.

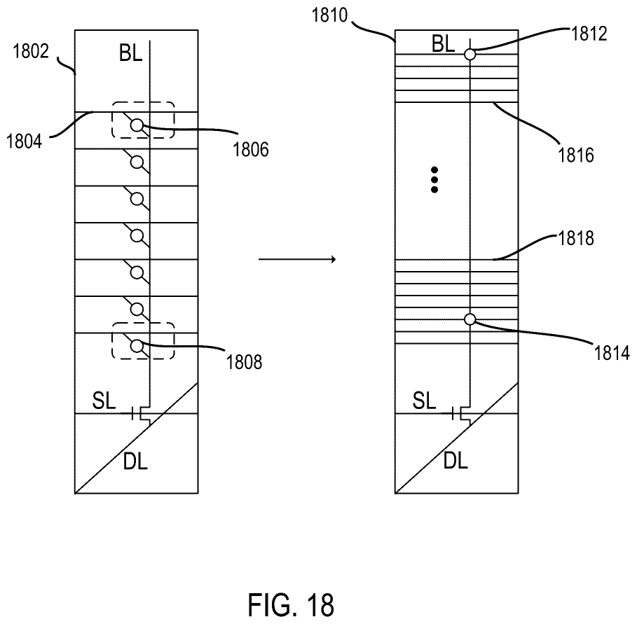

FIG. 18 shows an exemplary value encoded in a dense memory array and a corresponding encoding of the value in a sparse memory array according to one embodiment. Pillar 1802 contains memory cells arranged vertically along a bitline BL. The bitline is coupled to a digit line by a select transistor controlled using select line SL. Various ones of the memory cells are selected using wordlines 1804. Wordlines 1804 are arranged in tiers along the pillar.

Certain tiers are selected to program memory cells located in those selected tiers. Each memory cell has a terminal connected to one of wordlines 1804 and another terminal connected to bitline BL. In one embodiment, the controller applies write pulses to selected memory cells in selected tiers by biasing the bitline and the wordlines of those tiers. In one example, voltage biasing is applied using voltage drivers 115.

The memory cells of pillar 1802 are programmed to encode a value to be stored in the pillar 1802. In one example, the value corresponds to a stored weight. In one example, the stored weight is encoded using unary coding. In one example, the stored weight is updated as part of training a neural network.

For example, two memory cells 1806, 1808 are programmed to a logic 1 state (e.g., having a low threshold voltage). The other illustrated memory cells are at a logic 0 state (e.g., having a high threshold voltage).

Pillar 1802 is an example of a pillar in a dense memory array. The dense memory array is characterized as having a small number of total tiers as compared to the number of tiers having memory cells that will be programmed when storing values.

When storing a value and pillar 1802, a controller selects one or more wordlines 1804 to program memory cells. In a dense memory array, there is a higher probability that a selected tier will select a memory cell that has previously been programmed. In some cases, such memory cell may have less ability to be further programmed (e.g., the memory cell may have reached saturation). In one example, the extent of saturation can depend on the number of times that a memory cell has been previously programmed.

Pillar 1810 shows the same value of pillar 1802 as stored in a sparse memory array. For example, the value is encoded by programming memory cells 1812, 1814 to a logic 1 state. The sparse memory array is characterized as having a large number of total tiers as compared to the number of tiers having memory cells that will be programmed when storing values. For example, pillar 1810 includes 128 tiers. Each tier includes wordlines (e.g., 1816, 1818). Thus, pillar 1810 includes 128 total memory cells, of which only two memory cells are programmed. This characterizes the memory array as being sparse. In one example, a memory array can be considered sparse if a maximum of 30-60% of the total available memory cells will be programmed.

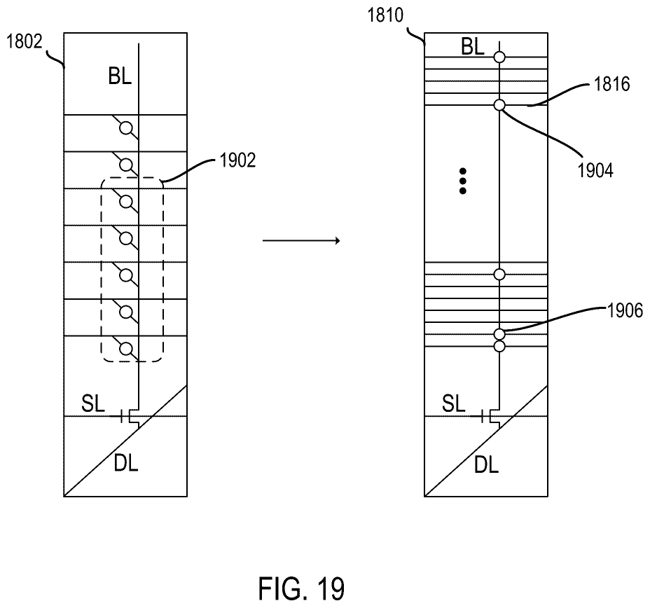

FIG. 19 shows another exemplary value encoded in a dense memory array and a corresponding encoding of the value in a sparse memory array according to one embodiment. For example, pillar 1802 stores a value using unary coding. The value is encoded based on programming memory cells 1902 to a logic 1 state.

This same value is encoded in pillar 1810 using unary coding. Pillar 1810 is provided in a sparse memory array. Thus, memory cells (e.g., 1904, 1906) that have been programmed to encode the value are dispersed amongst a larger total number of tiers as compared to the total number of tiers of pillar 1802.

In one embodiment, when programming memory cells to encode a stored value, various tiers are randomly selected by the controller from all the tiers of pillar 1810 (or from a defined set of tiers). Wordlines 1816 of selected tiers are used to program the memory cells 1904, 1906.

In one embodiment, random sparse unary coding is used. Within a given pillar in a synapse, a large number of cells (or all cells) are mapped to one synaptic cell such that the sum of currents of the multiple cells represent the unary value. Within a given pillar (e.g., 1810), when most of the cells are in an initial high resistance state (e.g., all cells have been reset or erased to have a high threshold voltage), randomly selecting a next one wordline WL from the pillar for updates is more likely to select a cell that has not previously been updated. In one example, the pillar has a total of 1,000 memory tiers.

The probability of updating a cell that has previously been updated increases as the number of updates increases. The extent of this saturation can be tracked by a controller counting write pulses to a cell (or a group of cells) or by measuring an output current from the cell (or from a group of cells). For example, a number of pulses can be a saturation limit. For example, a current magnitude can be a saturation limit.

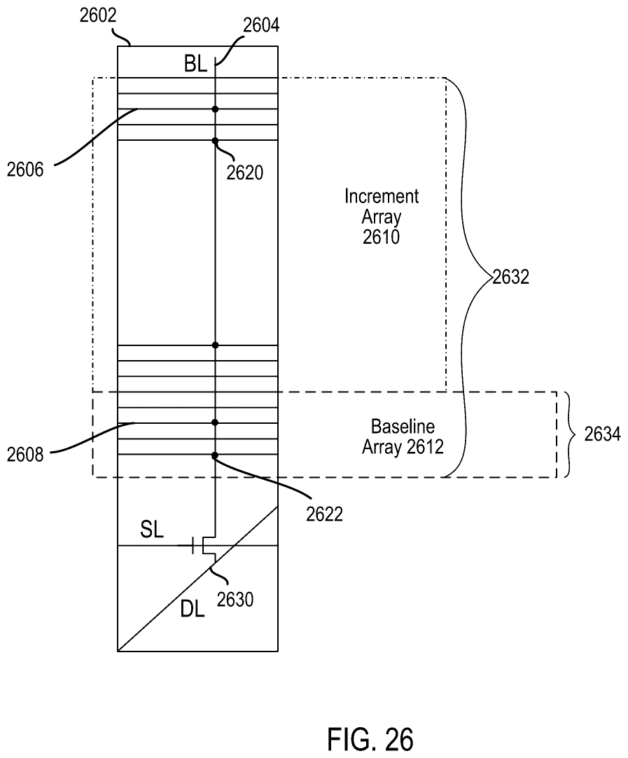

As regards saturation, during training and depending on the number of tiers allocated for training, the extent of saturation can be reset by encoding the pillar currents in a sparse array (e.g., increment array 2610 of FIG. 26) into a more dense portion of the array (e.g., baseline array 2612 of FIG. 26).

In one embodiment, increment and baseline arrays may reside within the same physical tile as a subset of tiers, or the baseline array can be moved into another tile. In one example, the increment array has 200-500 or more tiers, and the baseline array has 10-20 or less tiers (e.g., 3-8 tiers).

In one embodiment, sparse memory arrays are used to enable parallel synaptic weight changes (e.g., increments and decrements to the weight value). Specifically, the memory array is sparse in the wordline tiers. In this context, sparseness does not refer to the synaptic selectors.

In one embodiment, in a sparse memory array, a controller selects one or more wordlines at the same time. The wordlines are selected randomly. Use of randomly-selected wordline locations is more likely to select available memory cells (e.g., bits) to support incremental changes in most synapses.

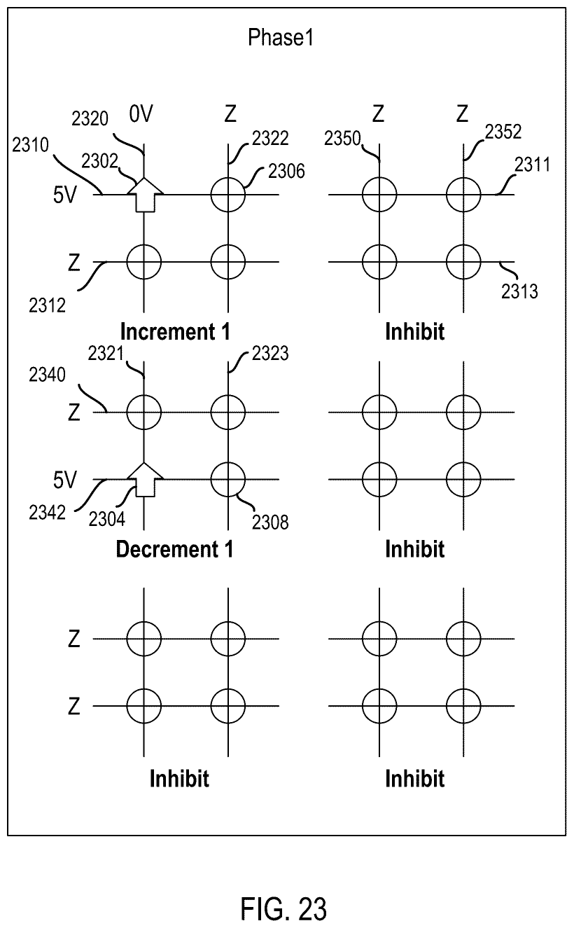

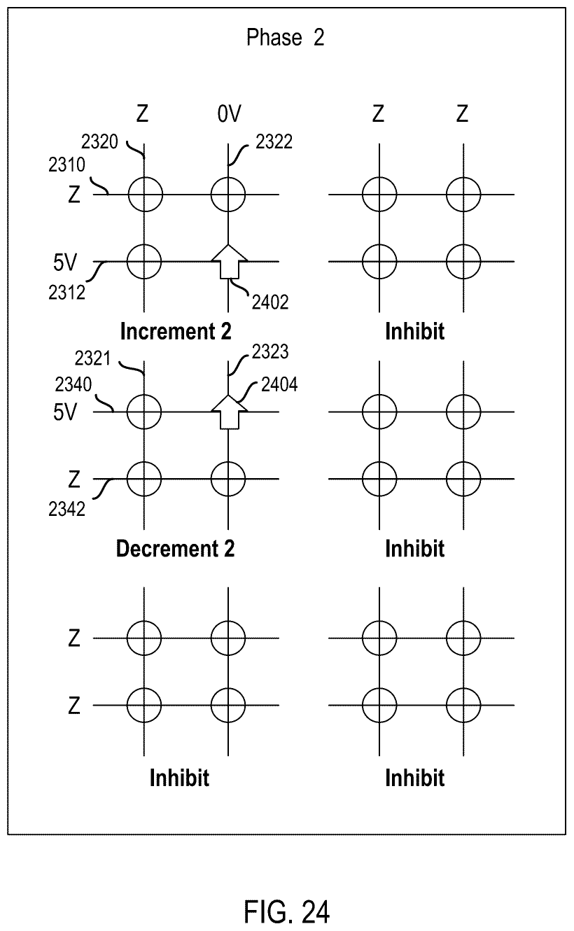

In one example, a sparse memory array begins operation with all memory cells in a logic 0 state. After a small number of memory cells have been programmed, most memory cells in the array are still in the logic 0 state. Changing the synaptic weight is supported by increment and decrement operations done by selecting a correct synapse quadrant (e.g., FIGS. 23-24 show examples of incrementing and decrementing synaptic weights using two phases of programming). The sparse memory array operation begins with a low common mode current (e.g., total accumulated current from memory cells) due to the memory cells being in the logic 0 state. The common mode current gradually increases as memory cells are programmed during operation.

In one example using chalcogenide-based memory cells, synaptic weight changes are done by parallel programming using multiple snapback or threshold events on a shared electrode (e.g., bitline BL). Each snapback or threshold event has the potential for modifying the state of the memory cell.

Use of a sparse memory array may provide one or more advantages. Variability can be improved due to averaging of memory cell characteristics over a large number of memory cells. This may reduce or remove a requirement for a placement algorithm when programming memory cells. Also, memory cell endurance can be improved because cell cycling effects are spread over all of the memory cells in the sparse array.

As the number of memory cells programmed increases over time, the ability of the memory cells to be further incremented will significantly decrease. This is referred to as saturation. When a controller determines that a saturation limit is reached, the memory cells of the sparse array are re-normalized (e.g., the stored weights in a pillar are transferred from the sparse array to a baseline array, such as described for FIG. 26). The memory cells are reset (e.g., cells are erased to logic 0 after transferring the weights to the baseline array).

A controller can determine that a saturation limit has been reached in various ways. In one example, the controller uses sensing circuitry to determine when a common mode current from a bitline or a digit line has reached the threshold. In one example, the controller uses sensing circuitry to determine that a voltage drop has exceeded a limit. In one example, the controller determines that a probability of being able to incrementally change a memory cell has fallen below a threshold probability.

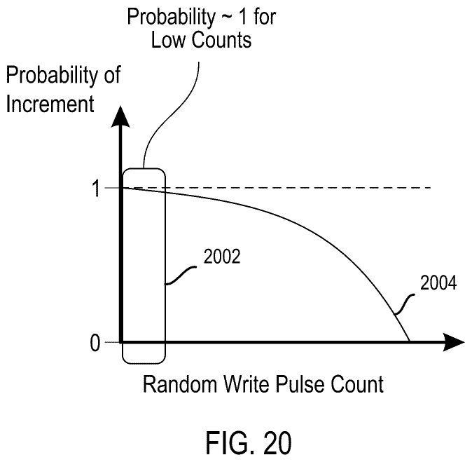

FIG. 20 shows an exemplary graph of a probability 2004 of being able to increment a memory cell versus a number of write pulses. For example, when all memory cells in a pillar have been reset to logic 0, the probability is 1. In other words, all memory cells are available for incremental programming. Over time, as incremental programming changes are randomly made to the memory cells, the probability of the next memory cell being selected being in a state that can be incremented (in other words, the cell is not saturated) decreases and eventually reaches zero.

Region 2002 indicates a region in which a small number of memory cells have been programmed (e.g., after a reset or re-normalization of the memory cells). The probability of randomly selecting a next tier for programming using write pulses in which memory cells are able to be incremented further is close to about one.

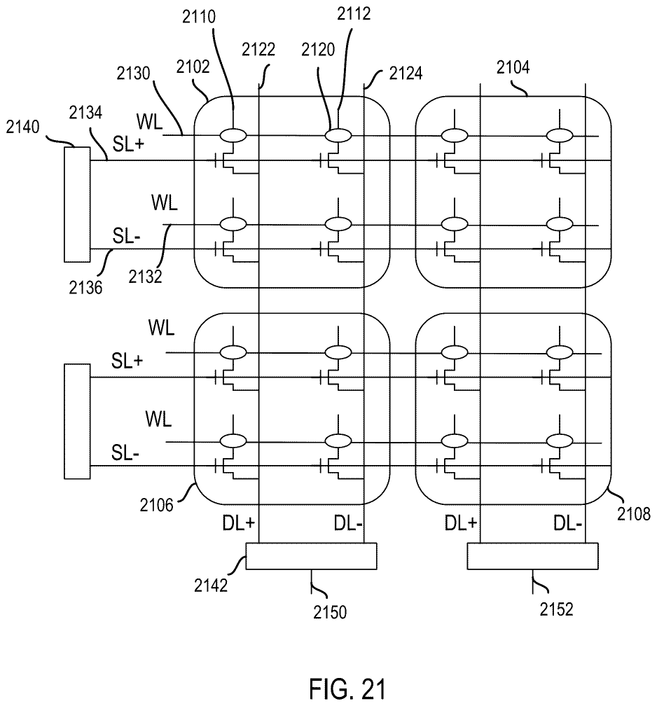

FIG. 21 shows a portion of a memory array having four synapses 2102, 2104, 2106, 2108 connected to digit lines 2122, 2124 used to accumulate output currents from memory cells of the synapses according to one embodiment. Each synapse has four memory cell locations (e.g., 2120) connected to bitlines (e.g., 2110, 2112) and wordlines (e.g., 2130, 2132).

During a multiplication operation, input signals are provided to the synapses using select lines 2134, 2136. Signals are generated by input circuitry 2140.

During the multiplication operation, output currents from the memory cells are accumulated on digit lines 2122, 2124. Accumulation circuitry 2142 uses these accumulated currents to generate digital results 2150, 2152 (e.g., using an analog to digital converter).

In one embodiment, each memory cell location 2120 corresponds to a pillar. For example, synapse 2102 has four pillars. In one example, each pillar is similar to pillar 1810.

Each memory illustrated cell location 2120 may correspond to one or more cells in an actual memory device. For example, memory cell location 2120 may correspond to several cells used to store a value using unary coding.

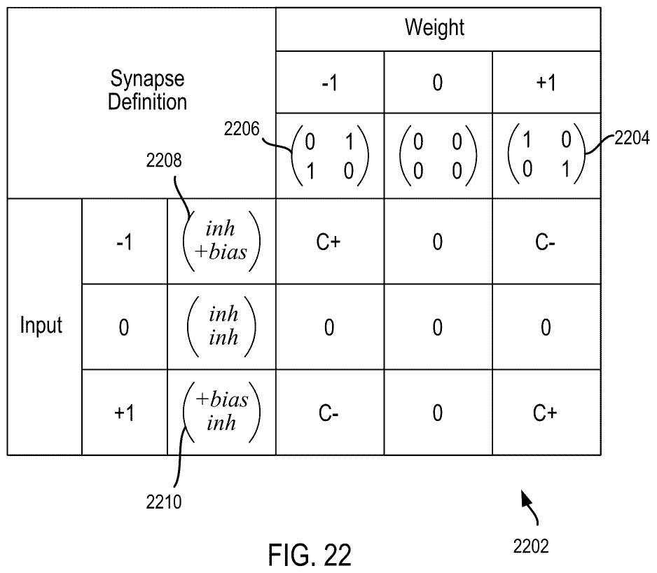

Each synapse stores a weight. The memory cells of each synapse are programmed to store values at the four memory cell locations that represent the weight and which are consistent with a four-quadrant synapse definition (e.g., synapse definition of FIG. 22).

In one embodiment, the synapses in a memory array are configured according to a four-quadrant synapse definition (e.g., FIG. 22). This enables the increment and decrement of each synaptic weight by adjusting the cell threshold of all memory cells of the synapses in only one direction (a same direction). For example, the threshold voltages of memory cells in the synapses are always decreased by applying one or more write pulses. By sequentially selecting the biases of access lines (e.g., wordlines, bitlines) in the array, parallel updates (e.g., increment and/or decrement of each synapse) can be achieved across an entire array of synapses.

In one embodiment, the memory cell thresholds are changed in gradual increments (e.g., each increment is a single write pulse; 4-8 pulses are needed for a full logic state change from 0 to 1). In one example, the memory cells are chalcogenide cells. The direction for gradual cell threshold adjustment is from high to low threshold (low conductance to high conductance). This allows for parallel selection of primarily high threshold cells (e.g., as discussed above for FIG. 19).

In one example, symmetric synaptic weight increment and decrement is supported using four-quadrant synapses. A gradual cell transition is used in only one direction. Each memory cell or collection of cells is bit-alterable in that direction. In one example, the cell transition includes a collection of cells in unary coding. The synapses are re-normalized when saturation is reached.

In an alternative embodiment, gradual cell threshold adjustment is not necessary when selection of multiple cells in parallel is sufficient to support a required synaptic resolution (e.g., the cells encode values using unary coding).

FIG. 22 shows a four-quadrant synapse definition. The definition provides a table of values for a product 2202 that corresponds to an input multiplied by a weight. The input and weight can each have positive and negative signs. For example, an input of −1 multiplied by a weight of +1 provides a product C− (e.g., −1). The value of C can be an arbitrary magnitude. In one example, the value of C is 1.

Matrices 2204, 2206 indicate the values stored in the four memory cells of a synapse that stores the corresponding weight. For example, matrix 2204 indicates logic states of the memory cells of synapse 2102 when storing a weight of +1. For example, matrix 2206 indicates logic states of the memory cells of synapse 2102 when storing a weight of-1.

Matrices 2208, 2210 indicate a voltage bias applied to a pair of select lines used to provide the signed input. For example, the pair of select lines include SL+ and SL− each connected to one or more select transistors (e.g., select lines 2134, 2136). For matrix 2208, the SL+ line is inhibited or in a high impedance state and no voltage bias is applied. A voltage bias is applied to the SL− line (e.g., that corresponds to the value of the input). For matrix 2210, a voltage bias is applied to the SL+ line, and the SL− line is inhibited or in a high impedance state.

FIGS. 23-24 show parallel updating of synaptic weights by programming memory cells in two phases according to one embodiment. For example, during a first or second phase, various synapses can be programmed so that the weight stored by the synapse is changed. The weight can be incremented (e.g., Increment 1), decremented (e.g., Decrement 1), or stay at the same value (e.g., Inhibit). The number of programming phases can be greater than two in other embodiments.

Each synapse has four memory cells at the intersections of wordlines and bitlines. For example, memory cells 2302, 2306 are accessed by wordline 2310, and bitlines 2320, 2322. The other memory cells of the synapse are accessed using wordline 2312.

All of the memory cells in the synapses are programmed in the same direction. For example, write pulses are applied to memory cells so that the threshold voltage of each memory cell decreases (or alternatively each decreases). It should be noted that the memory cells move in the same direction of change in state even though a particular synaptic weight having the memory cell can be incremented or decremented. For example, memory cell 2302 is programmed to decrease its threshold voltage. Memory cell 2304 is also programmed to decrease its threshold voltage.

In one embodiment, the memory cells are changed in gradual steps. Eventually, after multiple write pulses have been applied, a given memory cell cannot be changed any further because a saturation limit is reached.

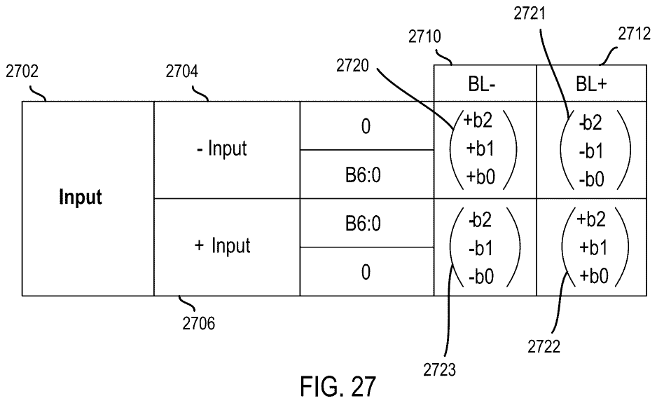

In one example, a synaptic weight is increased by applying appropriate voltage biases to wordlines 2310, 2312 and bitlines 2320, 2222. The voltage biases are applied according to a four-quadrant synapse definition (e.g., FIG. 22, FIG. 27). Memory cell 2302 is programmed in the first phase, and memory cell 2402 is programmed in a second phase. The value stored by memory cells 2302, 2402 is the same (the cells are on the same diagonal). The value stored by the other two memory cells on the opposite diagonal is zero.

In one example, a synaptic weight is decreased by applying appropriate voltage biases to wordlines 2340, 2342 and bitlines 2321, 2323. The voltage biases are applied according to the four-quadrant synapse definition. Memory cell 2304 is programmed in the first phase, and memory cell 2404 is programmed in the second phase. Memory cells 2304, 2404 have the same value and are on a first diagonal of the synapse. The memory cells 2308 on the opposite diagonal of the synapse store values of zero.

In one embodiment, bitlines 2320 and 2321 are the same bitline. Bitlines 2322 and 2323 are the same bitline. In one embodiment, wordlines 2310 and 2311 are the same wordline. Wordlines 2312 and 2313 are the same wordline.

During the first and second phases, some synaptic weights remain unchanged. For example, bitlines 2350, 2352 are not biased. Instead, the bitlines are inhibited or in high impedance state (indicated by “Z”). Thus, no memory cells of the synapse are changed.

Using the approach above, synaptic weights can be updated in parallel. For example, parallel updates can be performed within a bitline pair. For example, parallel updates can be performed within a wordline pair.

In one embodiment, the synapses shown in FIG. 23 are located on a single wordline tier.

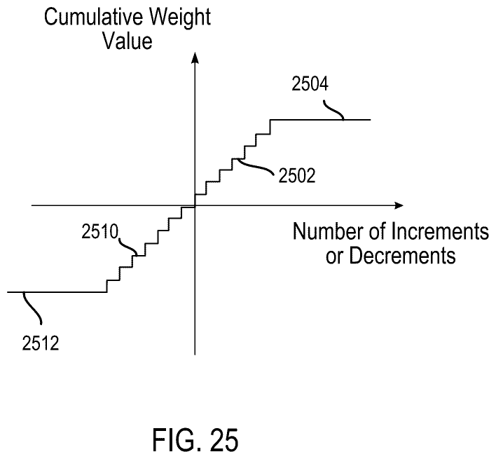

FIG. 25 shows an exemplary graph of cumulative synaptic weight value versus a number of increments or decrements to the synaptic weight. In one example, synapses are incremented or decremented as illustrated in FIGS. 23-24.

In one example, a weight of a synapse can be incremented in gradual steps 2502. The cumulative weight value increases. As the memory cells of the synapse saturate, the weight value reaches limit 2504.

Similarly, the weight of the synapse can be decremented in gradual steps 2510. The cumulative weight value decreases. As the memory cells of the synapse saturate, the weight value reaches limit 2512.

FIG. 26 shows an increment array 2610 and a baseline array 2612 according to one embodiment. In one example, pillar 2602 is one of many pillars in arrays 2610, 2612. Pillar 2602 has a bitline 2604 connected to memory cells 2620 in the increment array 2610 and to memory cells 2622 in the baseline array 2612. Wordlines 2606, 2608 are used to access the memory cells in the arrays.

The increment array 2610 is used during training to make gradual changes to synaptic weights in parallel (e.g., such as described above). Digit line 2630 is used to collect output currents from the memory cells.

In one embodiment, after training is completed, inference operations using pillar 2602 only use memory cells 2622 in baseline array 2612. Increment array 2610 is turned off. Thus, only portion 2634 of the memory cells are used.

During training, all memory cells 2632 of pillar 2602 are used. Gradual changes to weights are implemented by programming randomly selected tiers having cells 2620 in increment array 2610. These randomly selected cells do not include any cells in the baseline array 2612.

In one embodiment, during the main phase of training, output currents accumulated on digit line 2630 from all memory cells 2632 are sensed. During the forward pass evaluation phase of the training, only output currents from memory cells in portion 2634 of the baseline array 2612 are sensed.

In one embodiment, sufficient bits are allocated on a pillar to generate a desired granularity. In one embodiment, partial writes can be performed on memory cells (e.g., using multi-level cells such as TLC, QLC). This can extend dynamic range before statistical saturation of the memory cells in the pillar is reached.

In one example, the increment and baseline arrays can be split into multiple physical arrays. In one example, the increment array 2610 is implemented as a sparse memory array similarly as described for pillar 1810.

In one embodiment, a normalization operation is performed when approaching saturation. As part of this normalization, normalized values from increment array 2610 are transferred into baseline array 2612. Then, increment array 2610 is reset (e.g., all memory cells programmed to logic 0) (e.g., erase pulses are applied to increment array 2610). In one example, a bulk erase can be used. At the end of training, the increment array contributes minimally and is turned off.

In one embodiment, synapses are re-normalized when a controller determines that a threshold of some or all cells in a pillar has been increased or decreased to reach a threshold limit. As part of re-normalization, values of synapses in the array are read out, and the read value is then placed somewhere else in the array (or in a different array). Then, the controller resets the original array and re-uses the reset array (e.g., in subsequent training).

In one embodiment, a controller determines that a saturation limit is reached. The controller reads the entire current from all memory cells 2632 for the pillar and maps the corresponding value into, for example, a three bit value. The three-bit value is re-encoded into the baseline array 2612. By re-initializing the increment array in this manner, training can be continued.

In one embodiment, the baseline array uses a different memory technology from the increment array.

In one example, a controller determines a saturation limit is reached by measuring one or more currents from one or more pillars. If the measured current or currents exceeds the limit, then the controller determines that saturation has been reached.

In one example, memory cells 2620 are multi-level cells and partial writes are made to the cells. This way the memory cells can be more gradually adjusted. Each memory cell encodes multiple bits of resolution.

In one example, output current is sensed from memory cells of baseline array 2612 for forward pass evaluation. Then, the weights are adjusted. Forward pass evaluation is again performed, then weights are adjusted again, and so on until training is complete. It is noted that this forward pass is in contrast to the backward pass used in typical back-propagation training algorithms.

FIG. 27 shows exemplary encoding of an input signal 2702 and a synaptic weight according to one embodiment. The synaptic weight is represented by the values stored for corresponding memory cells of a synapse (a total of four cells is illustrated) as indicated by matrices 2720, 2721, 2722, 2723 of the synapse. In one example, the synaptic weight is stored in synapse 2102, 2104, 2106, or 2108.

The orientation of the corresponding memory cells relative to bitlines 2710, 2712 is illustrated. In one example, bitline 2710 corresponds to bitline 2110, and bitline 2712 corresponds to bitline 2112.

The sign of the weight is encoded by the orientation of the diagonal for the same stored values (+b2, +b1, +b0). In some cases, the diagonal in the opposite direction (sometimes referred to as an anti-diagonal) stores values of zero. The value of the weight is encoded by the bit pattern (+b2, +b1, +b0). In the illustrated example, three bits are used to encode the value. Both of the locations within a diagonal have matching patterns. A different number of bits can be used for each encoded value in other examples.

Input signal 2702 is a signed input. The sign of the input is encoded by the location of a signal on one of two wires (e.g., a select line pair). The value of the input is encoded by a bit pattern. In the illustrated example, the pattern includes seven bits B6 to B0.

For example, negative input 2704 has a zero value provided on a select SL+ line and an encoded pattern B6:0 on a select SL− line. Positive input 2706 has an encoded pattern B6:0 on a select SL+ line and a zero value provided on a select SL− line.

In one embodiment, each memory cell corresponding to one of matrices 2720, 2721, 2722, 2723 is a multi-level cell that can store multiple states or bits. In one embodiment, each memory cell location corresponding to one of the matrices is a set of cells that encode stored values using unary coding. In one embodiment, each memory cell location corresponding to one of the matrices is a set of three memory cells, with each cell having a different significance (e.g., MSB, MID, LSB).

In one example, accumulation circuitry collects a current on the plus bitline or on the minus bitline depending on the appropriate product (result). For example, for an input of −1, current is accumulated on the plus bitline, and no current is accumulated on the minus bitline. As illustrated in FIG. 27 and regarding the state of memory cells in a synapse: the pattern of cells on the diagonal match, and the pattern cells on the anti-diagonal match.

In one example, input signal 2702 is provided to a synapse using time slicing. In the time slicing, one bit at a time is multiplied by the synaptic weight and digital results (products) are accumulated. Accumulation circuitry then sums the products taking significance of the input bit into account. The difference in accumulated current between BL+ and BL− is the product of the multiplication for each bit.

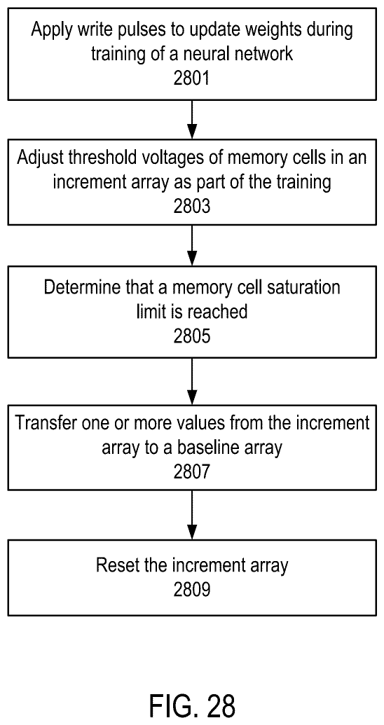

FIG. 28 shows a method for updating weights on a memory device during training of a neural network according to one embodiment. For example, the method of FIG. 28 can be performed in integrated circuit device 101 of FIG. 1 when performing multiplication (e.g., as described in various embodiments above).

The method of FIG. 28 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 28 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2801, write pulses are applied to update weights during training of a neural network. In one example, synaptic weights are incremented or decremented as described for FIGS. 23-24. In one example, tiers or wordlines are randomly selected for programming memory cells in pillar 1810.

At block 2803, threshold voltages of memory cells in an increment array are adjusted as part of the training. In one example, updating synaptic weights includes gradually stepping threshold voltages of memory cells in increment array 2610.

At block 2805, a controller determines that a memory cell saturation limit is reached. In one example, a controller determines that an accumulated current from a pillar exceeds a threshold.

At block 2807, one or more values are transferred from the increment array to a baseline array. In one example, a value encoded by memory cells 2620 is transferred to a value encoded by memory cells 2622.

At block 2809, the increment array is reset. In one example, memory cells in increment array 2610 are erased to have a high threshold voltage corresponding to a logic 0 state.

In some aspects, the techniques described herein relate to a system including: a plurality of synapses (e.g., 2102) each having memory cells; and at least one controller configured to update a respective weight stored by each synapse by changing threshold voltages of the memory cells in each synapse.

In some aspects, the techniques described herein relate to a system, wherein changing the threshold voltages includes applying program pulses to the memory cells in first and second phases (e.g., FIGS. 23-24).

In some aspects, the techniques described herein relate to a system, wherein a series of program pulses is applied to each memory cell.

In some aspects, the techniques described herein relate to a system, wherein a first memory cell of each synapse is programmed in the first phase, and a second memory cell of each synapse is programmed in the second phase.

In some aspects, the techniques described herein relate to a system, wherein the first and second memory cells are located on a first diagonal of the synapse.

In some aspects, the techniques described herein relate to a system, wherein the first and second memory cells are programmed to have a same value (e.g., +1 or −1).

In some aspects, the techniques described herein relate to a system, wherein a sign of the weight stored by each synapse is encoded by an orientation of the first diagonal of the synapse.

In some aspects, the techniques described herein relate to a system, wherein third and fourth memory cells of each synapse are located on a second diagonal of the synapse having an opposite direction from the first diagonal.

In some aspects, the techniques described herein relate to a system, wherein the third and fourth memory cells are programmed to have a same value (e.g., +1 or −1).

In some aspects, the techniques described herein relate to a system, wherein the third and fourth memory cells are programmed to have a value of zero.

In some aspects, the techniques described herein relate to a system, wherein each synapse is connected to first and second bitlines (e.g., 2320, 2322), and the respective weight of the synapse is updated by applying a voltage to the first bitline and inhibiting the second bitline in a first phase, and applying a voltage to the second bitline and inhibiting the first bitline in a second phase.

In some aspects, the techniques described herein relate to a system, wherein each synapse is connected to first and second wordlines (e.g., 2310, 2312), and the respective weight of the synapse is updated by applying a voltage to the first wordline and inhibiting the second wordline in a first phase, and applying a voltage to the second wordline and inhibiting the first wordline in a second phase.

In some aspects, the techniques described herein relate to a system, wherein the weights stored by the synapses can be selectively incremented or decremented by moving threshold voltages of the memory cells in a same direction of change (e.g., decreasing a threshold voltage of all memory cells).

In some aspects, the techniques described herein relate to a system, wherein each synapse has four quadrants, and each quadrant is configured to store a value.

In some aspects, the techniques described herein relate to a system, wherein the value in each quadrant is stored by a single multi-level cell (e.g., TLC or QLC).

In some aspects, the techniques described herein relate to a system, wherein the value in each quadrant is stored by multiple memory cells that encode the value using unary coding.

In some aspects, the techniques described herein relate to an apparatus including: a pillar (e.g., 1810, 2602) including first memory cells (e.g., 500 or more cells); and at least one controller configured to randomly select second memory cells (e.g., less than 10 cells) from the first memory cells when updating a stored weight.

In some aspects, the techniques described herein relate to an apparatus, wherein the stored weight is encoded using unary coding.

In some aspects, the techniques described herein relate to an apparatus, wherein the stored weight is updated as part of training a neural network.

In some aspects, the techniques described herein relate to an apparatus, wherein a sum of currents from the first memory cells represents a value of the stored weight.

In some aspects, the techniques described herein relate to an apparatus, wherein the first memory cells are arranged in tiers (e.g., tiers having wordlines 1816) along the pillar, and the second memory cells are selected by selecting one or more of the tiers.

In some aspects, the techniques described herein relate to an apparatus, wherein wordlines are connected to the first memory cells, and the second memory cells are selected by selecting one or more of the wordlines (e.g., 1816).

In some aspects, the techniques described herein relate to an apparatus, wherein the pillar further includes a bitline coupled to the first memory cells, and the controller is further configured to apply write pulses to the second memory cells by biasing the bitline and the selected wordlines.

In some aspects, the techniques described herein relate to a device including: an increment array (e.g., 2610); a baseline array (e.g., 2612); and at least one controller to configured to transfer a value stored in the increment array (e.g., a stored weight used in training, or a portion of a weight) to the baseline array.

In some aspects, the techniques described herein relate to a device, wherein the controller is further configured to determine whether at least one memory cell of the increment array has reached a saturation limit.

In some aspects, the techniques described herein relate to a device, wherein the value is transferred in response to determining that the memory cell has reached the saturation limit.

In some aspects, the techniques described herein relate to a device, wherein the saturation limit corresponds to an output current level of the at least one memory cell.

In some aspects, the techniques described herein relate to a device, wherein the increment array is configured to store a first value using a first number of memory cells (e.g., a value of 7 encoded by 7 cells using unary coding (1111111)), and the baseline array is configured to store the first value using a second number memory cells that is less than the first number (e.g., a value of 7 encoded by 3 cells using binary coding (111)).

In some aspects, the techniques described herein relate to a device, wherein the controller is further configured to reset the increment array after transferring the value.

In some aspects, the techniques described herein relate to a device, wherein resetting the increment array includes changing a state of a plurality of memory cells in the increment array (e.g., erasing the memory cells so that the increment array stores a value representing zero or a reset state).

In some aspects, the techniques described herein relate to a device, wherein changing the state includes changing a threshold voltage of the memory cells.

In some aspects, the techniques described herein relate to a device, wherein the controller is further configured to change an extent of usage of the increment array (e.g., turn off or disable usage) after training is stopped or completed.

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 203, 213, 223 of FIG. 2) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. A system comprising:
a plurality of synapses each having memory cells; and
at least one controller configured to update a respective weight stored by each synapse by changing threshold voltages of the memory cells in each synapse.

2. The system of claim 1, wherein changing the threshold voltages comprises applying program pulses to the memory cells in first and second phases.

3. The system of claim 2, wherein a series of program pulses is applied to each memory cell.

4. The system of claim 2, wherein a first memory cell of each synapse is programmed in the first phase, and a second memory cell of each synapse is programmed in the second phase.

5. The system of claim 4, wherein the first and second memory cells are located on a first diagonal of the synapse.

6. The system of claim 5, wherein the first and second memory cells are programmed to have a same value.

7. The system of claim 5, wherein a sign of the weight stored by each synapse is encoded by an orientation of the first diagonal of the synapse.

8. The system of claim 5, wherein third and fourth memory cells of each synapse are located on a second diagonal of the synapse having an opposite direction from the first diagonal.

9. The system of claim 8, wherein the third and fourth memory cells are programmed to have a same value.

10. The system of claim 9, wherein the third and fourth memory cells are programmed to have a value of zero.

11. The system of claim 1, wherein each synapse is connected to first and second bitlines, and the respective weight of the synapse is updated by applying a voltage to the first bitline and inhibiting the second bitline in a first phase, and applying a voltage to the second bitline and inhibiting the first bitline in a second phase.

12. The system of claim 1, wherein each synapse is connected to first and second wordlines, and the respective weight of the synapse is updated by applying a voltage to the first wordline and inhibiting the second wordline in a first phase, and applying a voltage to the second wordline and inhibiting the first wordline in a second phase.

13. The system of claim 1, wherein the weights stored by the synapses can be selectively incremented or decremented by moving threshold voltages of the memory cells in a same direction of change.

14. The system of claim 1, wherein each synapse has four quadrants, and each quadrant is configured to store a value.

15. The system of claim 14, wherein the value in each quadrant is stored by a single multi-level cell.

16. The system of claim 14, wherein the value in each quadrant is stored by multiple memory cells that encode the value using unary coding.

17. An apparatus comprising:
a pillar including first memory cells; and
at least one controller configured to randomly select second memory cells from the first memory cells when updating a stored weight.

18. The apparatus of claim 17, wherein the stored weight is encoded using unary coding.

19. The apparatus of claim 17, wherein the stored weight is updated as part of training a neural network.

20. The apparatus of claim 17, wherein a sum of currents from the first memory cells represents a value of the stored weight.

21. The apparatus of claim 17, wherein the first memory cells are arranged in tiers along the pillar, and the second memory cells are selected by selecting one or more of the tiers.

22. The apparatus of claim 17, wherein wordlines are connected to the first memory cells, and the second memory cells are selected by selecting one or more of the wordlines.

23. The apparatus of claim 22, wherein the pillar further includes a bitline coupled to the first memory cells, and the controller is further configured to apply write pulses to the second memory cells by biasing the bitline and the selected wordlines.

24. A device comprising:
an increment array;
a baseline array; and
at least one controller to configured to transfer a value stored in the increment array to the baseline array.

25. The device of claim 24, wherein the controller is further configured to determine whether at least one memory cell of the increment array has reached a saturation limit.

26. The device of claim 25, wherein the value is transferred in response to determining that the memory cell has reached the saturation limit.

27. The device of claim 25, wherein the saturation limit corresponds to an output current level of the at least one memory cell.

28. The device of claim 24, wherein the increment array is configured to store a first value using a first number of memory cells, and the baseline array is configured to store the first value using a second number memory cells that is less than the first number.

29. The device of claim 24, wherein the controller is further configured to reset the increment array after transferring the value.

30. The device of claim 29, wherein resetting the increment array comprises changing a state of a plurality of memory cells in the increment array.

31. The device of claim 30, wherein changing the state comprises changing a threshold voltage of the memory cells.

32. The device of claim 24, wherein the controller is further configured to change an extent of usage of the increment array after training is stopped or completed.
